(19) United States
(12) Patent Application Publication
(10) Pub. No.: US 2026/0206395 A1
(43) Pub. Date: Jul. 16, 2026

(54) DISPLAY APPARATUS AND ELECTRONIC DEVICES INCLUDING THE SAME

(71) Applicant: Samsung Display Co., LTD., Yongin-si (KR)

(72) Inventors: Changil TAE, Yongin-si (KR); Gyujeong LEE, Yongin-si (KR); Hyungil JEON, Yongin-si (KR)

(21) Appl. No.: 19/447,370

(22) Filed: Jan. 13, 2026

(30) Foreign Application Priority Data
Jan. 13, 2025 (KR) 10-2025-0004977

(51) Int. Cl. H10H 29/49; H10H 29/32; H10D 86/40; H10D 86/60

(52) U.S. Cl. CPC H10H 29/49; H10H 29/32; H10D 86/441; H10D 86/60

(57) ABSTRACT

A display apparatus includes a substrate, a transistor disposed on the substrate, a first-1 electrode pad electrically connected to the transistor, a first-1 bump metal connected to the first-1 electrode pad, a first light-emitting element electrically connected to the first-1 electrode pad through the first-1 bump metal, and a first-1 dam portion surrounding the first-1 bump metal.

This application claims priority to Korean Patent Application No. 10-2025-0004977, filed on January 13, 2025, and all the benefits accruing therefrom under 35 U.S.C. §119, the content of which is incorporated herein in its entirety by reference.

### BACKGROUND

### 1. Field

Embodiments of the disclosure relate to an apparatus, and more particularly, to a display apparatus and an electronic device including the same.

### 2. Description of the Related Art

Recently, electronic devices are being widely used. Electronic devices, such as mobile electronic devices and stationary electronic devices, are variously used. Such electronic devices include display apparatuses for providing visual information, such as images or videos, to users so as to support various functions.

With the development of display apparatuses visually displaying electrical signals, various display apparatuses having excellent characteristics such as a relatively small thickness, a relatively light weight, and a relatively low power consumption are being introduced. For example, flexible display apparatuses capable of being folded or rolled are being introduced. Recently, research and development of display apparatuses having various structures, such as stretchable display apparatuses having shapes that may variously change, are being actively conducted.

### SUMMARY

Embodiments of the disclosure provide a display apparatus, e.g., a flexible display apparatus.

However, such problems are examples and problems to be solved in the disclosure are not limited thereto.

In an embodiment of the disclosure, a display apparatus includes a substrate, a transistor disposed on the substrate, a first-1 electrode pad electrically connected to the transistor, a first-1 bump metal connected to the first-1 electrode pad, a first light-emitting element electrically connected to the first-1 electrode pad through the first-1 bump metal, and a first-1 dam portion surrounding the first-1 bump metal.

In an embodiment, an inner side of the first-1 dam portion may contact the first-1 bump metal.

In an embodiment, in a plan view, the first-1 dam portion may be disposed outside the first-1 electrode pad to surround the first-1 electrode pad.

In an embodiment, in a plan view, the first-1 dam portion may be disposed on the first-1 electrode pad along a perimeter of the first-1 electrode pad.

In an embodiment, the display apparatus may further include at least one align tip portion protruding from one side of the first-1 dam portion.

In an embodiment, the at least one align tip portion may include a same material as that of the first-1 dam portion.

In an embodiment, the display apparatus may further include a second electrode pad disposed next (adjacent) to the first-1 electrode pad, a second-1 bump metal connected to the second electrode pad to electrically connect the second electrode pad and the first light-emitting element to each other, and a second-1 dam portion surrounding the second-1 bump metal.

In an embodiment, the second electrode pad may be electrically connected to a common power line.

In an embodiment, the display apparatus may further include a first-2 electrode pad spaced apart from the first-1 electrode pad in a first direction, a first-2 bump metal connected to the first-2 electrode pad and electrically connecting the first-2 electrode pad to a second light-emitting element, and a first-2 dam portion surrounding the first-2 bump metal.

In an embodiment, the second electrode pad may be spaced apart from the first-1 electrode pad and the first-2 electrode pad in a second direction crossing the first direction.

In an embodiment, the display apparatus may further include a second-2 bump metal connected to the second electrode pad to electrically connect the second electrode pad and a second light-emitting element to each other, and a second-2 dam portion surrounding the second-2 bump metal, wherein, in a plan view, the second electrode pad may overlap the second-1 bump metal and the second-2 bump metal.

In an embodiment, the second-1 dam portion and the second-2 dam portion may be spaced apart from each other in a first direction.

In an embodiment, a portion of the second-1 dam portion facing the second-2 dam portion may be disposed on the second electrode pad, and a remaining portion of the second-1 dam portion may be disposed outside the second electrode pad.

In an embodiment, the first-1 dam portion may include a same material as that of the second-1 dam portion, and the first-1 dam portion and the second-1 dam portion may be arranged in a same layer.

In an embodiment of the disclosure, a display apparatus including a display area and a non-display area outside the display area, further includes a plurality of first island portions arranged in the display area, and a first bridge portion connecting two first island portions next (adjacent) to each other from among the plurality of first island portions, wherein each of the plurality of first island portions includes a substrate, a transistor disposed on the substrate, a first electrode pad electrically connected to the transistor, a first bump metal connected to the first electrode pad, a first light-emitting element electrically connected to the first electrode pad through the first bump metal, and a first dam portion surrounding the first bump metal.

In an embodiment, each of the plurality of first island portions may further include a third dam portion disposed along a perimeter of each of the plurality of first island portions.

In an embodiment, the third dam portion may include a same material as that of the first dam portion and may be disposed in a same layer as the first dam portion.

In an embodiment, the display apparatus may further include a plurality of second island portions disposed in the non-display area, and a second bridge portion connecting two second island portions next (adjacent) to each other from among the plurality of second island portions, each of the plurality of second island portions may include a fourth dam portion disposed along a perimeter of each of the plurality of second island portions.

In an embodiment, the fourth dam portion may include a same material as that of the third dam portion and may be disposed in a same layer as the third dam portion.

In an embodiment of the disclosure, an electronic device including a display, further includes a display apparatus corresponding to the display, and a frame accommodating the display apparatus, wherein the display apparatus includes a substrate, a transistor disposed on the substrate, a first electrode pad electrically connected to the transistor, a first bump metal connected to the first electrode pad, a first light-emitting element electrically connected to the first electrode pad through the first bump metal, and a first dam portion surrounding the first bump metal.

Other features and advantages other than those described above will become apparent from the detailed descriptions, claims and drawings for carrying out the following disclosure.

By embodiments of the disclosure, there may be provided a display apparatus in which an electrical connection of a light-emitting element may be stably maintained and an electronic device including the display apparatus.

The effects of the disclosure are not limited to those mentioned above, and other effects that are not mentioned may be clearly understood by one of ordinary skill in the art from the scope of claims.

### BRIEF DESCRIPTION OF DRAWINGS

The above and other embodiments, advantages and features of this disclosure will become more apparent by describing in further detail embodiments thereof with reference to the accompanying drawings.

FIG. 1 is a perspective view schematically showing an embodiment of a display apparatus according to the disclosure.

FIGS. 2A and 2B are perspective views showing the display apparatus of FIG. 1 stretched in a first direction.

FIG. 2C is a perspective view showing the display apparatus of FIG. 1 stretched in a second direction.

FIG. 2D is a perspective view showing the display apparatus of FIG. 1 stretched in the first direction and the second direction.

FIG. 2E is a perspective view showing the display apparatus of FIG. 1 stretched in a third direction.

FIG. 3 is a plan view schematically showing an embodiment of a display apparatus according to the disclosure.

FIG. 4A is an enlarged plan view of a region IV of an embodiment of FIG. 3 as a portion of a display apparatus, according to the disclosure.

FIG. 4B is an enlarged plan view of the region IV of an embodiment of FIG. 3 as a portion of a display apparatus, according to the disclosure.

FIG. 4C is an enlarged plan view of the region IV of an embodiment of FIG. 3 as a portion of a display apparatus, according to the disclosure.

FIG. 5 is a cross-sectional view of an embodiment of a first island portion and a first bridge portion, which are arranged in a display area of a display apparatus, according to the disclosure.

FIGS. 6A to 6C are each an equivalent circuit diagram of an embodiment of a sub-pixel of a display apparatus, according to the disclosure.

FIG. 7 is a plan view schematically showing an embodiment of a first island portion of a display apparatus, according to the disclosure.

FIG. 8 is a plan view of excerpts of an embodiment of first and second electrode pads, a light-emitting diode, and dam portions, which are arranged in a first island portion of a display apparatus, according to the disclosure.

FIG. 9 is a cross-sectional view of an embodiment of a first island portion of a display apparatus taken along line IX-IX' of FIG. 8, according to the disclosure.

FIG. 10 is a plan view of excerpts of an embodiment of first and second electrode pads, a light-emitting diode, and dam portions, which are arranged in a first island portion of a display apparatus, according to the disclosure.

FIG. 11 is a plan view of excerpts of an embodiment of first and second electrode pads, a light-emitting diode, and dam portions, which are arranged in a first island portion of a display apparatus, according to the disclosure.

FIG. 12 is a cross-sectional view of an embodiment of a first island portion of a display apparatus taken along line XII-XII' of FIG. 11, according to the disclosure.

FIG. 13 is a plan view schematically showing an embodiment of a second island portion of a display apparatus, according to the disclosure.

FIGS. 14A to 14G are each a perspective view of an embodiment of an electronic device including a display apparatus, according to the disclosure.

### DETAILED DESCRIPTION

The disclosure may have various modifications and various embodiments, and illustrative embodiments are illustrated in the drawings and are described in detail in the detailed description. Effects and features of the disclosure and methods of achieving the same will become apparent with reference to embodiments described in detail below with reference to the drawings. However, the disclosure is not limited to the embodiments described below, and may be implemented in various forms.

Hereinafter, embodiments of the disclosure will be described in detail with reference to the accompanying drawings, and in the following description with reference to the drawings, like reference numerals refer to like components and redundant descriptions thereof will be omitted.

In the following embodiments, the terms "first" and "second" are not used in a limited sense and are used to distinguish one component from another component.

In the following embodiments, an expression used in the singular encompasses the expression of the plural, unless it has a clearly different meaning in the context.

In the following embodiments, the terms such as "comprise" or "include" specify the presence of stated features or components, but do not preclude the addition of one or more other features or components.

In the following embodiments, when a part such as a layer, a region, or a component is referred to as being "on" or "above" another part, the part may be directly on the other part or another layer, region, or component may be present therebetween.

In the following embodiments, when a layer, region, component, or the like is connected to another layer, region, component, or the like, the layer, the region, the component, or the like may be directly connected thereto and/or may be indirectly connected thereto with an intervening layer, region, component, or the like therebetween. Also, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

In the drawings, for convenience of description, sizes of components may be exaggerated or reduced. For example, because sizes and thicknesses of components in the drawings are arbitrarily illustrated for convenience of explanation, the disclosure is not necessarily limited thereto.

In the following embodiments, "A and/or B" denotes only A, only B, or both A and B. Also, "at least one of A and B" denotes only A, only B, or both A and B.

In the following embodiments, when a wire "extends in a first direction or a second direction," the wire may not only extend in linearly, but also extend in zigzags or in a curve along the first direction or the second direction.

In the following embodiments, "in a plan view" indicates that a target portion is viewed from above. In the following embodiments, "in a cross-sectional view" indicates that a cross-section of a target portion cut vertically is viewed from side. In the following embodiments, when a first component "overlaps" a second component, the first component may be located on or below the second component.

In the following embodiments, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

When an illustrative embodiment may be implemented differently, a specific process order may be performed differently from the described order. For example, two consecutively described processes may be performed substantially at the same time or performed in an order opposite to the described order.

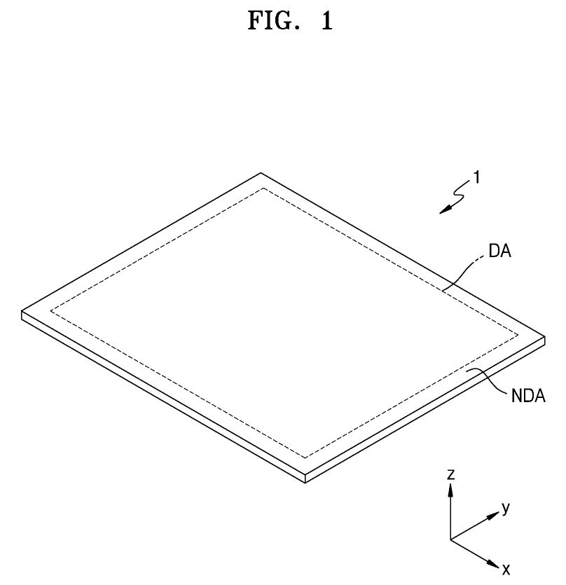

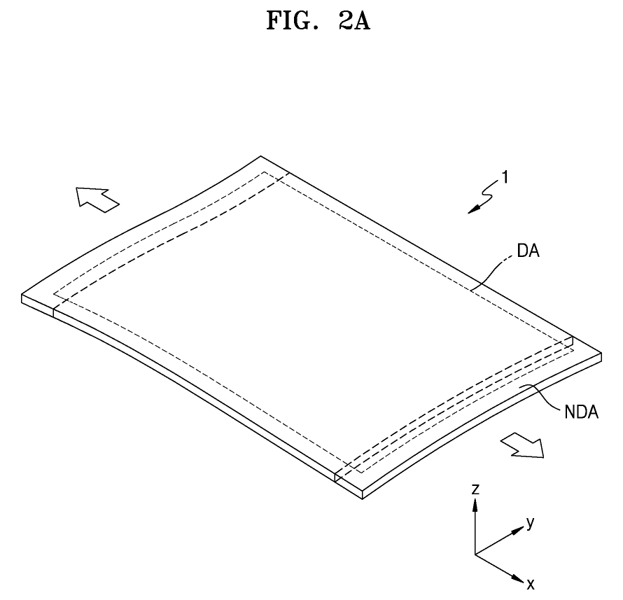

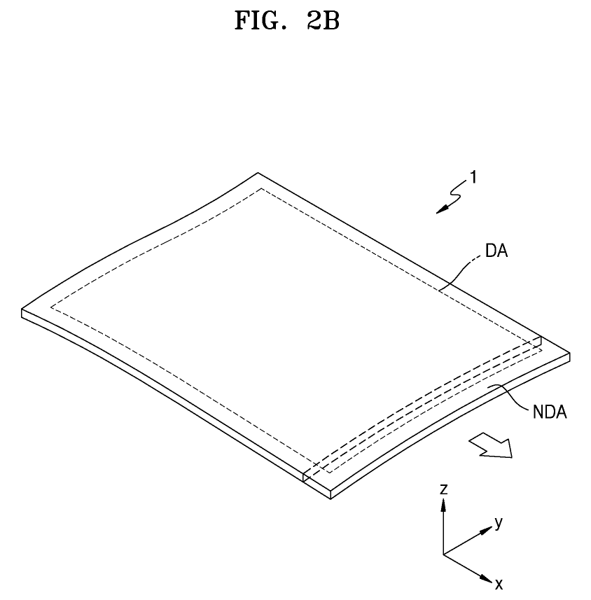

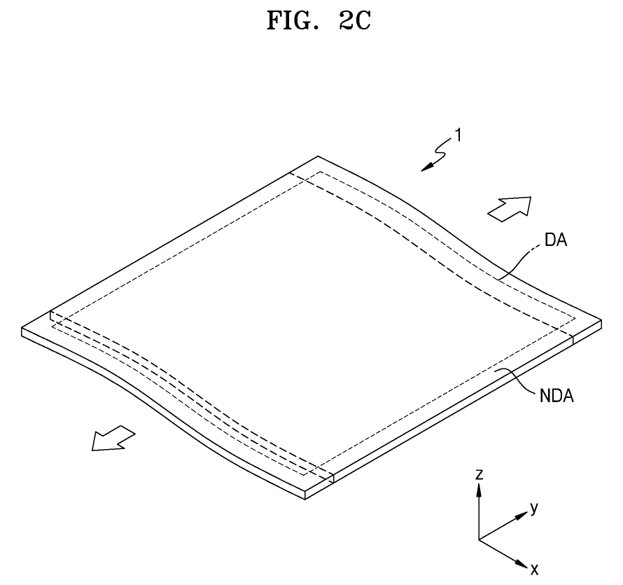

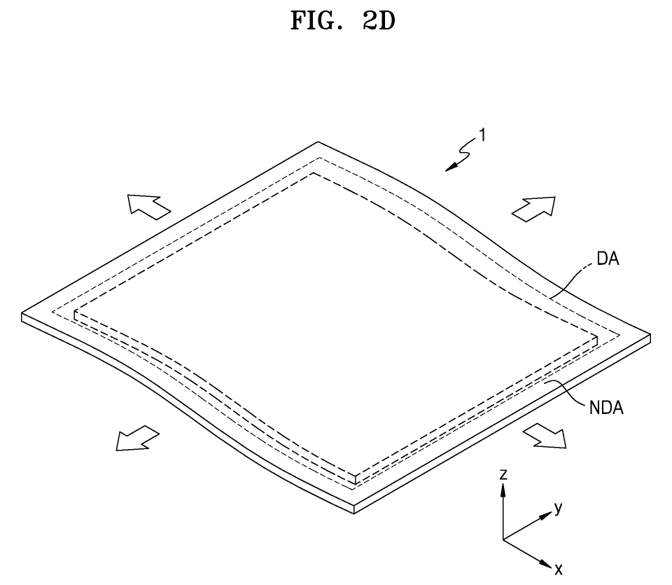

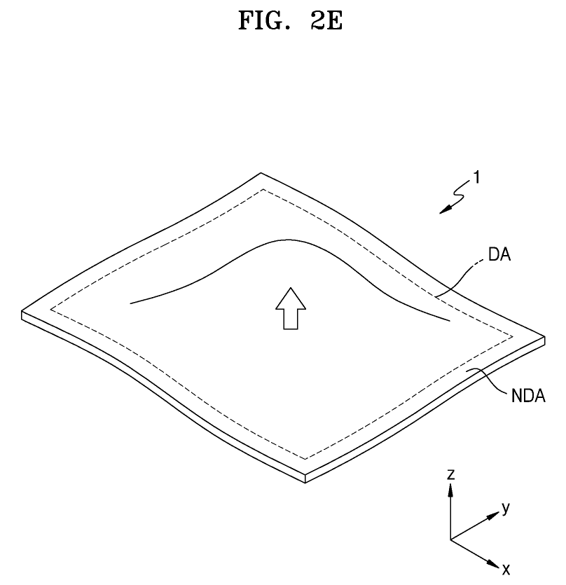

FIG. 1 is a perspective view schematically showing an embodiment of a display apparatus 1 according to the disclosure. FIGS. 2A and 2B are perspective views showing the display apparatus 1 of FIG. 1 stretched in a first direction. FIG. 2C is a perspective view showing the display apparatus 1 of FIG. 1 stretched in a second direction. FIG. 2D is a perspective view showing the display apparatus 1 of FIG. 1 stretched in the first direction and the second direction. FIG. 2E is a perspective view showing the display apparatus 1 of FIG. 1 stretched in a third direction.

Referring to FIG. 1, the display apparatus 1 may include a display area DA and a non-display area NDA. The display area DA may include a plurality of pixels. The display apparatus 1 may provide a predetermined image by light emitted from the plurality of pixels. The non-display area NDA may be disposed outside the display area DA. The non-display area NDA is an area where pixels are not arranged and may surround an entirety of the display area DA.

The display apparatus 1 may be stretched or contracted in various directions. The display apparatus 1 may be stretched in the first direction (e.g., an x direction and/or a -x direction) by an external force applied by an external object or a user. In an embodiment, as shown in FIGS. 2A and 2B, the display area DA and/or the non-display area NDA of the display apparatus 1 may be stretched in the first direction (e.g., the x direction and/or the -x direction). In an embodiment, the display apparatus 1 may be stretched along the x direction and the -x direction as shown in FIG. 2A, or along the x direction while one side of the display apparatus 1 is fixed as shown in FIG. 2B, for example.

The display apparatus 1 may be stretched in the second direction (e.g., a y direction and/or a -y direction) by an external force applied by an external object or the user. In an embodiment, as shown in FIG. 2C, the display area DA and/or the non-display area NDA of the display apparatus 1 may be stretched in the y direction and the -y direction. In another embodiment, the display area DA and/or the non-display area NDA may be stretched in the y direction or the -y direction while one side of the display apparatus 1 is fixed.

The display apparatus 1 may be stretched in a plurality of directions, e.g., the first direction (e.g., the x direction and/or the -x direction) and the second direction (e.g., the y direction and/or the -y direction), by an external force applied by an external object or a part of the body of a person. As shown in FIG. 2D, the display area DA and/or the non-display area NDA of the display apparatus 1 may be stretched in the ±x direction and the ±y direction.

The display apparatus 1 may be stretched in the third direction (e.g., a z direction or a -z direction) by an external force applied by an external object or a part of the body of a person. In an embodiment, FIG. 2E illustrates a portion of the display apparatus 1, e.g., a partial area of the display area DA, protruding in the z direction. In another embodiment, a portion of the display apparatus 1, e.g., a partial area of the display area DA, may protrude along the -z direction (or be dented along the z direction).

As shown in FIGS. 2A to 2E, the display apparatus 1 is stretched in the first direction, the second direction, and/or the third direction, but the disclosure is not limited thereto. In another embodiment, the display apparatus 1 may be variously transformed in an atypical shape, for example, may be bent or twisted about two or more axes.

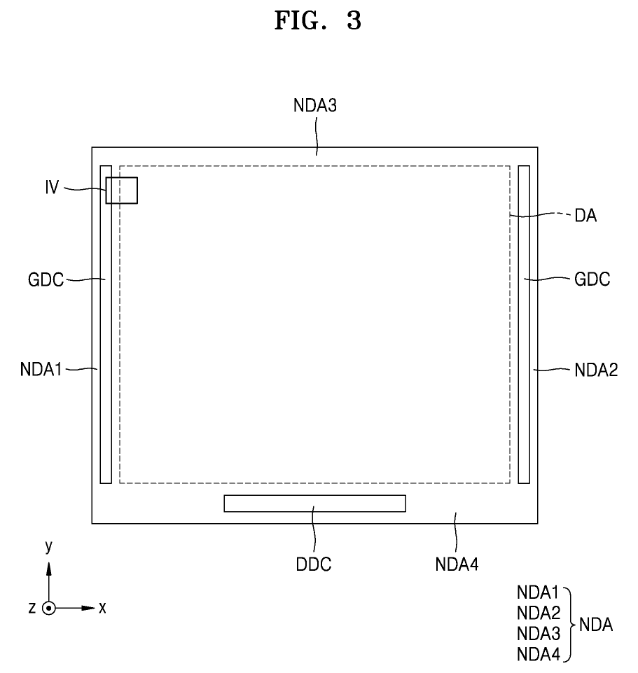

FIG. 3 is a plan view schematically showing the display apparatus 1 according to the disclosure.

The plurality of pixels may be arranged in the display area DA of the display apparatus 1. Each pixel may include sub-pixels emitting light of different colors. A light-emitting element corresponding to each sub-pixel may be disposed in the display area DA. A circuit which provides electrical signals to the light-emitting elements arranged in the display area DA and transistors electrically connected to the light-emitting elements may be disposed in the non-display area NDA surrounding the display area DA. A gate driving circuit GDC may be disposed in each of a first non-display area NDA1 and a second non-display area NDA2, which are arranged on opposite sides with the display area DA therebetween. The gate driving circuit GDC may include drivers which provide electrical signals respectively to gate electrodes of the transistors electrically connected to the light-emitting elements. In FIG. 3, the gate driving circuit GDC is disposed in each of the first non-display area NDA1 and the second non-display area NDA2, but the disclosure is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4, which is extended to the first non-display area NDA1 and the second non-display area NDA2 to each other. In an embodiment, FIG. 3 illustrates the data driving circuit DDC being disposed in the fourth non-display area NDA4. In another embodiment, the data driving circuit DDC may be disposed in each of the third non-display area NDA3 and the fourth non-display area NDA4.

FIG. 3 illustrates the data driving circuit DDC being disposed in the fourth non-display area NDA4 of the display apparatus 1, but the disclosure is not limited thereto. In another embodiment, the display apparatus 1 may further include a flexible circuit board (not shown) electrically connected through a terminal portion (not shown) disposed in the fourth non-display area NDA4, and the data driving circuit DDC may be disposed on the flexible circuit board.

In some embodiments, an elongation of the non-display area NDA may be equal to or lower than an elongation of the display area DA. In an embodiment, the elongation of the non-display area NDA may be different according to areas. In an embodiment, the first non-display area NDA1, the second non-display area NDA2, and the third non-display area NDA3 may have substantially a same elongation, but an elongation of the fourth non-display area NDA4 may be lower than the elongation of each of the first non-display area NDA1, the second non-display area NDA2, and the third non-display area NDA3, for example. In the specification, the elongation is a value that represents a change (ΔL/L) in a length by which the display apparatus 1 is stretchable without any physical damage when an external force is applied to the display apparatus 1. Here, ΔL denotes the amount of change in the length of the display apparatus 1 and L denotes the initial length of the display apparatus 1.

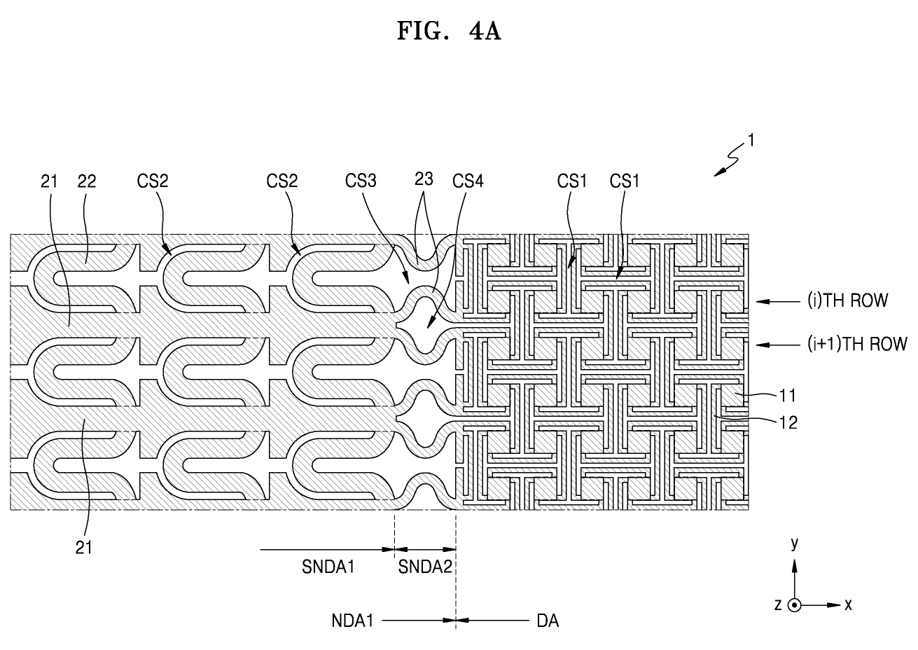

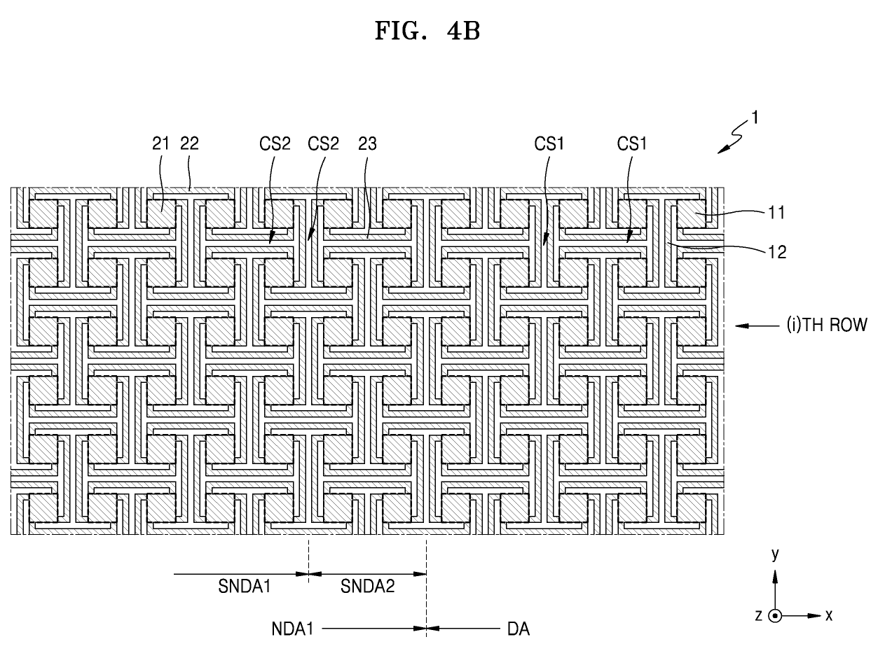

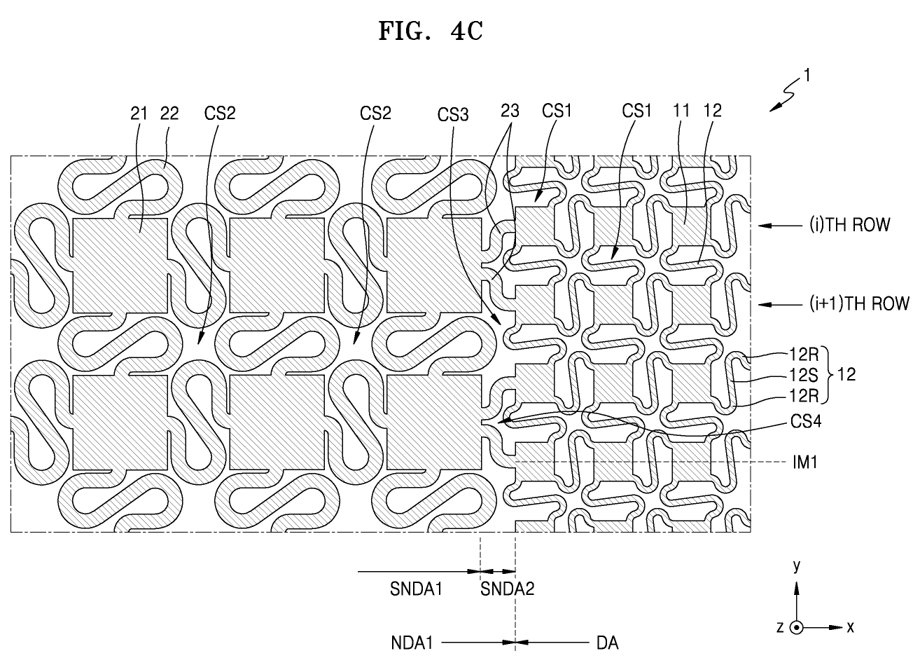

FIG. 4A is an enlarged plan view of a region IV of FIG. 3 as a portion of the display apparatus 1, according to the disclosure.

Referring to FIG. 4A, the display apparatus 1 may include first island portions 11 that are spaced apart from each other in the first direction (e.g., the x direction or the -x direction) and the second direction (e.g., the y direction or the -y direction) in the display area DA, and first bridge portions 12 connecting the first island portions 11 next (adjacent) to each other.

Each first island portion 11 may be connected to the plurality of first bridge portions 12. In an embodiment, each first island portion 11 may be connected to four first bridge portions 12, for example. Two first bridge portions 12 may be arranged on opposite sides of the first island portion 11 in the first direction (e.g., the x direction or the -x direction), and the remaining two first bridge portions 12 may be arranged on opposite sides of the first island portion 11 in the second direction (e.g., the y direction or the -y direction). In an embodiment, the four first bridge portions 12 may be connected to four sides of the first island portion 11, respectively. The four first bridge portions 12 may be next (adjacent) to corners of the first island portion 11, respectively.

The first bridge portions 12 may be spaced apart from each other by a first opening portion CS1 disposed between the first bridge portions 12. In an embodiment, the first opening portion CS1 having an approximately H-shape and the first opening portion CS1 having an approximately I-shape obtained by rotating the H-shape by 90 degrees may be alternately and repeatedly arranged along the first direction (e.g., the x direction or the -x direction) and the second direction (e.g., the y direction or the -y direction). Opposite end portions of each first bridge portion 12 may be respectively connected to the first island portions 11 next (adjacent) to each other, and one side of each first bridge portion 12 may be spaced apart from one side of the first island portion 11 and/or one side of another first bridge portion 12 next (adjacent) to each other by the first opening portion CS1.

The display apparatus 1 may include, in a non-display area, e.g., in the first non-display area NDA1 of FIG. 4A, second island portions 21 spaced apart from each other and second bridge portions 22 extending to the second island portions 21 next (adjacent) to each other.

Each second island portion 21 may extend in the first direction (e.g., the x direction or the -x direction). The second island portions 21 may be spaced apart from each other in the second direction (e.g., the y direction or the -y direction) crossing the first direction (e.g., the x direction or the -x direction). Each second island portion 21 may include drivers of the gate driving circuit GDC (FIG. 3) described with reference to FIG. 3.

The second bridge portion 22 may have a serpentine shape. A length of the second bridge portion 22 may be greater than a shortest distance between the second island portions 21 next (adjacent) to each other in the second direction (e.g., the y direction or the -y direction). In an embodiment, the second bridge portion 22 may have an approximate shape of an omega (Ω) convex in the first direction (e.g., the x direction or the -x direction). The second bridge portions 22 may be arranged between the second island portions 21 next (adjacent) to each other while being spaced apart from each other.

The second bridge portions 22 between the second island portions 21 next (adjacent) to each other may be spaced apart from each other by a second opening portion CS2. The second opening portions CS2 and the second bridge portions 22 may be alternately arranged in the first direction (e.g., the x direction or the -x direction), between the second island portions 21 next (adjacent) to each other. The second opening portions CS2 may have a same shape. Opposite end portions of each second bridge portion 22 may be respectively extended to the second island portions 21 next (adjacent) to each other, and one side of each second bridge portion 22 may be spaced apart from one side of the second island portion 21 and/or one side of another second bridge portion 22 next (adjacent) to each other by the second opening portion CS2.

One second island portions 21 arranged in the first non-display area NDA1 may correspond to the first island portions 11 of a plurality of rows arranged in the display area DA. In an embodiment, one second island portions 21 arranged in the first non-display area NDA1 may correspond to the first island portions 11 arranged in an (i)th row and the first island portions 11 arranged in an (i+1)th row of the display area DA, wherein i is a positive number greater than 1, for example. In FIG. 4A, one second island portion 21 corresponds to two rows of the first island portions 11, but the disclosure is not limited thereto. In another embodiment, one second island portion 21 arranged in the first non-display area NDA1 may correspond to n rows of the first island portions 11 arranged in the display area DA, wherein n is a positive number of 3 or more).

The non-display area, e.g., the first non-display area NDA1, may include a first sub-non-display area SNDA1 where the second island portions 21 and the second bridge portions 22 described above are arranged, and a second sub-non-display area SNDA2 between the first sub-non-display area SNDA1 and the display area DA. Third bridge portions 23 for connecting the display area DA and the first sub-non-display area SNDA1 to each other may be arranged in the second sub-non-display area SNDA2. One end portion of the third bridge portion 23 may be extended to the second island portion 21 and/or the second bridge portion 22, and an opposite end portion of the third bridge portion 23 may be connected to the first island portion 11 and/or extended to the first bridge portion 12.

The third bridge portion 23 may have a serpentine shape. In an embodiment, a shape of the third bridge portion 23 may be different from a shape of each of the first bridge portion 12 and the second bridge portion 22. In an embodiment, as shown in FIG. 4A, the third bridge portion 23 may have an approximate shape of an omega (Ω) convex in the second direction (e.g., the y direction or the -y direction). The third bridge portions 23 arranged next (adjacent) to each other in the second direction (e.g., the y direction or the -y direction) may have a symmetric structure, wherein one of the third bridge portions 23 is convex in the y direction and a remaining (the other) one of the third bridge portions 23 is convex in the -y direction. A third opening portion CS3 and a fourth opening portion CS4, which have different shapes, may be repeated between the third bridge portions 23. A width of the third bridge portion 23 may be different from a width of the first bridge portion 12 and a width of the second bridge portion 22. In an embodiment, the width of the third bridge portion 23 may be greater than the width of the first bridge portion 12 and smaller than the width of the second bridge portion 22.

In FIG. 4A, the second island portion 21 and the second bridge portion 22 in the non-display area, e.g., the first non-display area NDA1, respectively have different shapes from the first island portion 11 and the first bridge portion 12 in the display area DA. In another embodiment of the disclosure, the second island portion 21 and the second bridge portion 22 in the non-display area may have same shapes as the first island portion 11 and the first bridge portion 12 in the display area DA, respectively.

FIG. 4B is an enlarged plan view of the region IV of FIG. 3 as a portion of the display apparatus 1, according to the disclosure.

Referring to FIG. 4B, the display apparatus 1 includes, in the display area DA, the first island portions 11 spaced apart from each other, and the first bridge portions 12 spaced apart from each other by the first opening portion CS1 and connecting the first island portions 11 next (adjacent) to each other. A structure of the display area DA of FIG. 4B may be the same as a structure of the display area DA described above with reference to FIG. 4A.

The display apparatus 1 may include the second island portions 21 and the second bridge portions 22 in a non-display area, e.g., the first non-display area NDA1. In an embodiment, the second island portions 21 and the second bridge portions 22 may have substantially the same shapes as the first island portions 11 and the first bridge portions 12, respectively.

The second island portions 21 may be spaced apart from each other in the first direction (e.g., the x direction or the -x direction) and the second direction (e.g., the y direction or the -y direction) in the non-display area, e.g., the first non-display area NDA1. Each of the second bridge portions 22 may connect the second island portions 21 next (adjacent) to each other. The second bridge portions 22 may be spaced apart from each other by the second opening portion CS2 disposed between the second bridge portions 22.

The second opening portion CS2 may have substantially the same shape as that of the first opening portion CS1. In an embodiment, the second opening portion CS2 having an approximately H-shape and the second opening portion CS2 having an approximately I-shape may be repeatedly and alternately arranged in the non-display area, e.g., the first non-display area NDA1, for example. The opposite end portions of each second bridge portion 22 may be respectively connected to the second island portions 21 next (adjacent) to each other, and one side of each second bridge portion 22 may be spaced apart from one side of the next (adjacent) second island portion 21 and/or one side of another second bridge portion 22 next (adjacent) to each other by the second opening portion CS2.

Each second island portion 21 may be connected to the four second bridge portions 22. Each second island portion 21 may include the drivers of the gate driving circuit GDC (FIG. 3) described with reference to FIG. 3.

The second island portions 21 of one row arranged in the first non-display area NDA1 may correspond to the first island portions 11 of one row arranged in the display area DA. In an embodiment, the second island portions 21 arranged in an (i)th row in the first direction (e.g., the x direction or the -x direction) in the first non-display area NDA1 may correspond to the first island portions 11 arranged in a same row (e.g., the (i)th row) in the display area DA, wherein i is a positive number greater than 0, for example.

The display apparatus 1 may include the third bridge portions 23 arranged in the second sub-non-display area SNDA2 to connect the display area DA and the first sub-non-display area SNDA1 to each other. The non-display area, e.g., the first non-display area NDA1, may include the first sub-non-display area SNDA1 where the second island portions 21 and the second bridge portions 22 are arranged, and the second sub-non-display area SNDA2 including the third bridge portions 23 and disposed between the first sub-non-display area SNDA1 and the display area DA. The third bridge portion 23 may be substantially the same as the first bridge portion 12 and the second bridge portion 22. In an embodiment, the width of the third bridge portion 23 may be the same as the width of the first bridge portion 12 and the width of the second bridge portion 22, for example.

FIG. 4C is an enlarged plan view of the region IV of FIG. 3 as a portion of the display apparatus, according to the disclosure.

Referring to FIG. 4C, the display apparatus 1 may include the first island portions 11 that are spaced apart from each other in the first direction (e.g., the x direction or the -x direction) and the second direction (e.g., the y direction or the -y direction) in the display area DA, and the first bridge portions 12 connecting the first island portions 11 next (adjacent) to each other.

The first bridge portions 12 may be spaced apart from each other by the first opening portion CS1 disposed between the first bridge portions 12. The first bridge portion 12 may have a serpentine shape. In an embodiment, as shown in FIG. 4C, the first bridge portion 12 may include an approximate shape of a letter "S" by including two round portions 12R and a straight portion 12S between the two round portions 12R, for example.

Each first island portion 11 may be extended to the plurality of first bridge portions 12. In an embodiment, each first island portion 11 may be extended to four first bridge portions 12, for example. Two first bridge portions 12 may be arranged on opposite sides of the first island portion 11 in the first direction (e.g., the x direction or the -x direction), and the remaining two first bridge portions 12 may be arranged on opposite sides of the first island portion 11 in the second direction (e.g., the y direction or the -y direction). The four first bridge portions 12 may be extended to four sides of the first island portion 11, respectively. The four first bridge portions 12 may be next (adjacent) to corners of the first island portion 11, respectively.

The display apparatus 1 may include the second island portions 21 spaced apart from each other in the first direction (e.g., the x direction or the -x direction) and the second direction (e.g., the y direction or the -y direction) in the non-display area, e.g., the first non-display area NDA1 of FIG. 4C, and the second bridge portions 22 connecting the second island portions 21 next (adjacent) to each other.

The second bridge portions 22 may be spaced apart from each other by the second opening portion CS2 disposed between the second bridge portions 22. The second bridge portion 22 may have a serpentine shape. In an embodiment, as shown in FIG. 4C, the second bridge portion 22 may have an approximate shape of a letter "S". A size and/or a width of the second bridge portion 22 may be different from a size and/or a width of the first bridge portion 12, for example. In an embodiment, the size and/or the width of the second bridge portion 22 may be greater than the size and/or the width of the first bridge portion 12, for example. A radius of curvature of a round portion of the second bridge portion 22 may be different from a radius of curvature of the round portion of the first bridge portion 12. In an embodiment, the radius of curvature of the round portion of the second bridge portion 22 may be greater than the radius of curvature of the round portion of the first bridge portion 12, for example.

Each second island portion 21 may be extended to the plurality of second bridge portions 22. Each second island portion 21 may be extended to the four second bridge portions 22. Two second bridge portions 22 may be arranged on opposite sides of the second island portion 21 in the first direction (e.g., the x direction or the -x direction), and the remaining two second bridge portions 22 may be arranged on opposite sides of the second island portion 21 in the second direction (e.g., the y direction or the -y direction). In an embodiment, the four second bridge portions 22 may be extended to four sides of the second island portion 21, respectively. Each second bridge portion 22 may be extended to a center portion of each side of the second island portion 21.

The second island portions 21 of one row arranged in the first non-display area NDA1 may correspond to the first island portions 11 of a plurality of rows arranged in the display area DA. In an embodiment, the second island portions 21 of one row arranged in the first non-display area NDA1 may correspond to the first island portions 11 arranged in an (i)th row and the first island portions 11 arranged in an (i+1)th row of the display area DA, wherein i is a positive number greater than 1, for example. In another embodiment, the second island portions 21 of one row may correspond to n rows of the first island portions 11, wherein n is a positive number of 3 or greater.

The non-display area, e.g., the first non-display area NDA1, may include the first sub-non-display area SNDA1 where the second island portions 21 and the second bridge portions 22 described above are arranged, and the second sub-non-display area SNDA2 between the first sub-non-display area SNDA1 and the display area DA. The third bridge portions 23 for connecting the display area DA and the first sub-non-display area SNDA1 to each other may be disposed in the second sub-non-display area SNDA2. One end portion of the third bridge portion 23 may be extended to the second island portion 21 and an opposite end portion of the third bridge portion 23 may be extended to the first island portion 11. In an embodiment, the one end portion of the third bridge portion 23 may be extended to a center portion of one side of the second island portion 21 and an opposite end portion of the third bridge portion 23 may be extended to a center portion of one side of the first island portion 11, for example.

The third bridge portion 23 may have a serpentine shape. In an embodiment, a shape of the third bridge portion 23 may be different from a shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and smaller than the width of the second bridge portion 22. The third opening portion CS3 and the fourth opening portion CS4, which have different shapes, may be alternately arranged between the third bridge portions 23 in the second direction (e.g., the y direction or the -y direction).

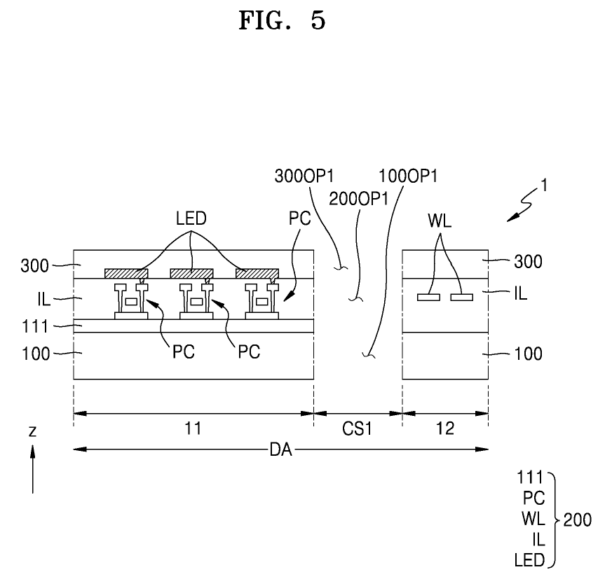

FIG. 5 is a cross-sectional view of the first island portion 11 and the first bridge portion 12, which are arranged in the display area DA of the display apparatus 1, according to the disclosure.

Referring to FIG. 5, the first island portion 11 and the first bridge portion 12, which are arranged in the display area DA, may be spaced apart from each other with the first opening portion CS1 therebetween. The first island portion 11 may include light-emitting elements LED and a circuit, e.g., a pixel driving circuit portion PC, electrically connected thereto and driving the light-emitting elements LED, and the first bridge portion 12 may include a wire WL electrically connected to the pixel driving circuit portions PC arranged in the first island portions 11 next (adjacent) to each other, respectively.

Referring to the first island portion 11, a buffer layer 111 including an inorganic insulating material may be disposed on a substrate 100, and the pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and electrically connected to the corresponding pixel driving circuit portion PC. The light-emitting elements LED may emit lights of different colors or lights of a same color. In an embodiment, each of the light-emitting elements LED may emit red, green, or blue light. In some embodiments, the light-emitting elements LED may emit white light. In another embodiment, each of the light-emitting elements LED may emit red, green, blue, or white light.

The substrate 100 may include a polymer resin such as polyether sulfone, polyacrylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may be a single layer including the polymer resin described above. In another embodiment, the substrate 100 may have a multi-layer structure including a base layer including the polymer resin described above, and a barrier layer including an inorganic insulating material. The substrate 100 including the polymer resin may be flexible, rollable, or bendable.

In an embodiment, in FIG. 5, three pixel driving circuit portions PC are arranged in each first island portion 11, and three light-emitting elements LED are connected to each pixel driving circuit portion PC, but the disclosure is not limited thereto. In another embodiment, the numbers of pixel driving circuit portions PC and light-emitting elements LED arranged in the first island portion 11 may be one, two, or four or more.

An encapsulation layer 300 may be disposed on the light-emitting element LED and may protect the light-emitting element LED from an external force and/or moisture permeability. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked on each other. In another embodiment, the encapsulation layer 300 may include an organic material such as resin. In some embodiments, the encapsulation layer 300 may include urethane epoxy acrylate. The encapsulation layer 300 may include a photosensitive material, e.g., photoresist.

Referring to the first bridge portion 12, the insulating layer IL including an organic insulating material may be disposed on the substrate 100. The first bridge portion 12 that is relatively deformed a lot when the display apparatus 1 is stretched may not include a layer including an inorganic insulating material, which is easily cracked, unlike the first island portion 11.

In an embodiment, the substrate 100 corresponding to the first bridge portion 12 may have a same stack structure as the substrate 100 corresponding to the first island portion 11. In an embodiment, the substrate 100 corresponding to the first bridge portion 12 and the substrate 100 corresponding to the first island portion 11 may be polymer resin layers formed together through a same process. In another embodiment, the substrate 100 corresponding to the first bridge portion 12 may have a different stack structure from the substrate 100 corresponding to the first island portion 11. In some embodiments, the substrate 100 corresponding to the first island portion 11 may have a multi-layer structure including a base layer including polymer resin and a barrier layer including an inorganic insulating material, and the substrate 100 corresponding to the first bridge portion 12 may have a structure of a polymer resin layer without a layer including an inorganic insulating material.

As described above, the wires WL of the first bridge portion 12 may be signal lines (e.g., a gate line, a data line, or the like) for providing an electrical signal to a transistor included in the pixel driving circuit portion PC of the first island portion 11, or voltage lines (e.g., a driving voltage line, an initialization voltage line, or the like) for providing a voltage. The encapsulation layer 300 may also be disposed in the first bridge portion 12. In another embodiment, the encapsulation layer 300 may not be in the first bridge portion 12.

Referring to FIGS. 4A to 4C and 5, the substrate 100 corresponding to the first island portion 11 and the substrate 100 corresponding to the first bridge portion 12 may be connected to each other. In other words, the plan views of FIGS. 4A to 4C above may be substantially the same as the plan view of the substrate 100 of FIG. 5. In other words, the substrate 100 may include an area corresponding to the first island portion 11, an area corresponding to the first bridge portion 12, and an opening 100OP1 having a same shape as that of the first opening portion CS1.

Similarly, the encapsulation layer 300 corresponding to the first island portion 11 and the encapsulation layer 300 corresponding to the first bridge portion 12 may be connected to each other. In an embodiment, the plan views of FIGS. 4A to 4C above may be substantially the same as the plan view of the encapsulation layer 300, for example. In other words, the encapsulation layer 300 may include an area corresponding to the first island portion 11, an area corresponding to the first bridge portion 12, and an opening 300OP1 having a same shape as that of the first opening portion CS1.

A circuit-light-emitting element layer 200 between the substrate 100 and the encapsulation layer 300 may include the buffer layer 111, the pixel driving circuit portion PC, the wire WL, the insulating layer IL, and the light-emitting element LED. Similarly to the substrate 100, the plan views of FIGS. 4A to 4C above may be substantially the same as the plan view of the circuit-light-emitting element layer 200. In other words, the circuit-light-emitting element layer 200 may define an opening 200OP1 having a same shape as that of the first opening portion CS1.

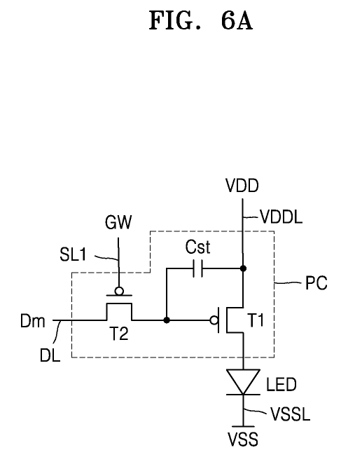

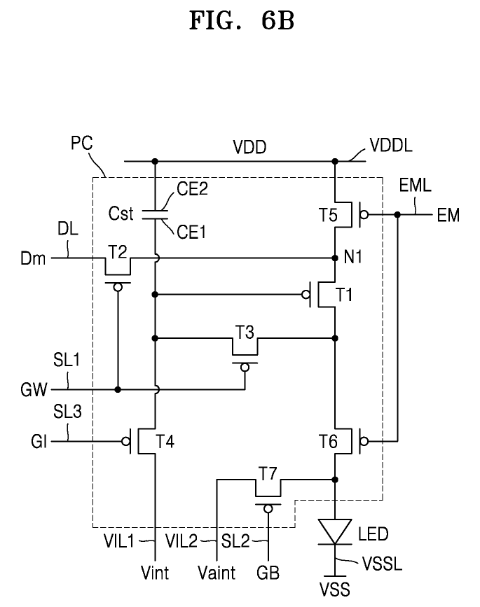

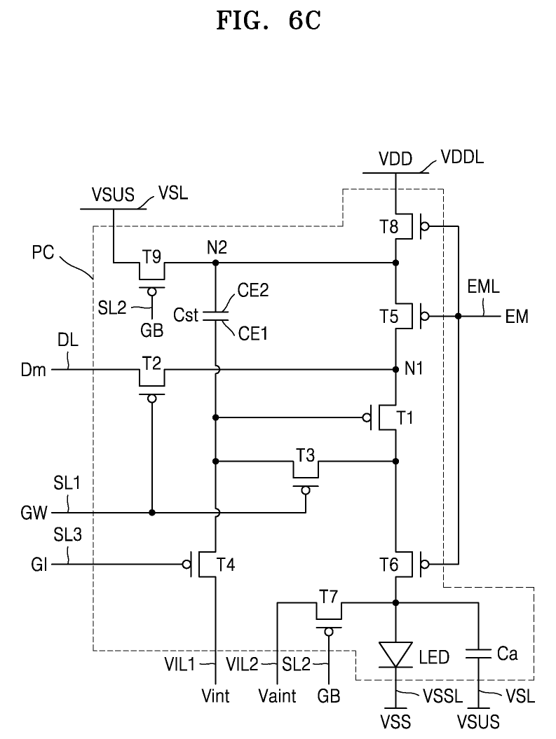

FIGS. 6A to 6C are each an equivalent circuit diagram of a sub-pixel of the display apparatus 1, according to the disclosure.

Referring to FIG. 6A, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit, to the first transistor T1, a data signal Dm input from the data line DL, according to the first scan signal GW input from the first scan line SL1.

The storage capacitor Cst may be electrically connected to the second transistor T2 and the first voltage line VDDL, and may store a voltage corresponding to a difference between a voltage received from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL, in response to a value of a voltage stored in the storage capacitor Cst. The light-emitting element LED may emit a light of a predetermined luminance according to the driving current. A first electrode of the light-emitting element LED may be electrically connected to the first transistor T1, and a second electrode thereof may be electrically connected to a second voltage line VSSL which supplies a second power voltage VSS.

In FIG. 6A, the pixel driving circuit portion PC includes two transistors and one storage capacitor, but in another embodiment, the pixel driving circuit portion PC may include three or more transistors.

Referring to FIG. 6B, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include the data line DL and gate lines such as the first scan line SL1, a second scan line SL2, a third scan line SL3, and an emission control line EML. The voltage lines may include a first initialization voltage line VIL1, a second initialization voltage line VIL2, and the first voltage line VDDL.

The first voltage line VDDL may transmit the first power voltage VDD to the first transistor T1. The first initialization voltage line VIL1 may transmit, to the pixel driving circuit portion PC, a first initialization voltage Vint for initializing the first transistor T1. The second initialization voltage line VIL2 may transmit, to the pixel driving circuit portion PC, a second initialization voltage Vaint for initializing the first electrode of the light-emitting element LED.

The first transistor T1 may be electrically connected to the first voltage line VDDL via the fifth transistor T5, and electrically connected to the light-emitting element LED via the sixth transistor T6. The first transistor T1 operates as a driving transistor and supplies a driving current to the light-emitting element LED by receiving the data signal Dm according to a switching operation of the second transistor T2.

The second transistor T2 is a data write transistor and electrically connected to the first scan line SL1 and the data line DL. The second transistor T2 is electrically connected to the first voltage line VDDL via the fifth transistor T5. The second transistor T2 is turned on according to a first scan signal GW received through the first scan line SL1 to perform a switching operation of transmitting the data signal Dm transmitted to the data line DL, to a first node N1.

The third transistor T3 is electrically connected to the first scan line SL1 and electrically connected to the light-emitting element LED via the sixth transistor T6. The third transistor T3 may be turned on according to the first scan signal GW received through the first scan line SL1 and diode-connect the first transistor T1.

The fourth transistor T4 is a first initialization transistor and is electrically connected to the third scan line SL3 and the first initialization voltage line VIL1. The fourth transistor T4 may be turned on according to a third scan signal GI received through the third scan line SL3 to initialize a voltage of the gate electrode of the first transistor T1 by transmitting the first initialization voltage Vint from the first initialization voltage line VIL1 to the gate electrode of the first transistor T1. The third scan signal GI may correspond to a first scan signal from another pixel driving circuit portion disposed in a previous row of the corresponding pixel driving circuit portion PC.

The fifth transistor T5 may be an operation control transistor and the sixth transistor T6 may be an emission control transistor. The fifth transistor T5 and the sixth transistor T6 may be electrically connected to the emission control line EML and simultaneously turned on according to an emission control signal EM received through the emission control line EML, thereby forming a current path for the driving current to flow in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB received through the second scan line SL2, and may initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and a second electrode CE2. The first electrode CE1 is electrically connected to the gate electrode of the first transistor T1 and the second electrode CE2 is electrically connected to the first voltage line VDDL. The storage capacitor Cst may maintaining a voltage applied to the gate electrode of the first transistor T1 by storing and maintaining a voltage corresponding to a difference between opposite end voltages of the first voltage line VDDL and the gate electrode of the first transistor T1.

Referring to FIG. 6C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include the data line DL and gate lines such as the first scan line SL1, the second scan line SL2, the third scan line SL3, and the emission control line EML. The voltage lines may include the first initialization voltage line VIL1, the second initialization voltage line VIL2, a sustain voltage line VSL, and the first voltage line VDDL.

The first voltage line VDDL may transmit the first power voltage VDD to the first transistor T1. The first initialization voltage line VIL1 may transmit, to the pixel driving circuit portion PC, the first initialization voltage Vint for initializing the first transistor T1. The second initialization voltage line VIL2 may transmit, to the pixel driving circuit portion PC, the second initialization voltage Vaint for initializing the first electrode of the light-emitting element LED. The sustain voltage line VSL may provide a sustain voltage VSUS to a second node N2, e.g., the second electrode CE2 of the storage capacitor Cst, during an initialization period and a data write period.

The first transistor T1 may be electrically connected to the first voltage line VDDL via the fifth transistor T5 and the eighth transistor T8, and electrically connected to the light-emitting element LED via the sixth transistor T6. The first transistor T1 operates as a driving transistor and may supply the driving current to the light-emitting element LED by receiving the data signal Dm according to a switching operation of the second transistor T2.

The second transistor T2 is electrically connected to the first scan line SL1 and the data line DL, and electrically connected to the first voltage line VDDL via the fifth transistor T5 and the eighth transistor T8. The second transistor T2 is turned on according to the first scan signal GW received through the first scan line SL1 to perform a switching operation of transmitting the data signal Dm transmitted to the data line DL, to the first node N1.

The third transistor T3 is electrically connected to the first scan line SL1 and electrically connected to the light-emitting element LED via the sixth transistor T6. The third transistor T3 may be turned on according to the first scan signal GW received through the first scan line SL1 and diode-connect the first transistor T1, thereby compensating for a threshold voltage of the first transistor T1.

The fourth transistor T4 may be connected to the third scan line SL3 and the first initialization voltage line VIL1, and turned on according to the third scan signal GI received through the third scan line SL3 to transmit the first initialization voltage Vint from the first initialization voltage line VIL1 to the gate electrode of the first transistor T1, thereby initializing a voltage of the gate electrode of the first transistor T1. The third scan signal GI may correspond to a first scan signal from another pixel driving circuit portion disposed in a previous row of the corresponding pixel driving circuit portion PC.

The fifth transistor T5, the sixth transistor T6, and the eighth transistor T8 may be electrically connected to the emission control line EML and simultaneously turned on according to the emission control signal EM received through the emission control line EML, thereby forming a current path for the driving current to flow in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to the second scan signal GB received through the second scan line SL2, and may initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on according to the second scan signal GB received through the second scan line SL2, and may transmit the sustain voltage VSUS to the second node N2, e.g., the second electrode CE2 of the storage capacitor Cst, in the initialization period and the data write period.

The eighth transistor T8 and the ninth transistor T9 may be each electrically connected to the second node N2, e.g., the second electrode CE2 of the storage capacitor Cst. In some embodiments, the eighth transistor T8 may be turned off and the ninth transistor T9 may be turned on in the initialization period and the data write period, and the eighth transistor T8 may be turned on and the ninth transistor T9 may be turned off in an emission period. The sustain voltage VSUS is transmitted to the second node N2 in the initialization period and the data write period, and thus, uniformity (e.g., long range uniformity (“LRU”)) of luminance of the display apparatus according to a voltage drop of the first voltage line VDDL may be enhanced.

The storage capacitor Cst includes the first electrode CE1 and the second electrode CE2. The first electrode CE1 is electrically connected to the gate electrode of the first transistor T1 and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca stores and maintains a voltage corresponding to a voltage difference between the first electrode of the light-emitting element LED and the sustain voltage line VSL while the seventh transistor T7 and the ninth transistor T9 are turned on, thereby preventing an increase in black luminance when the sixth transistor T6 is turned off.

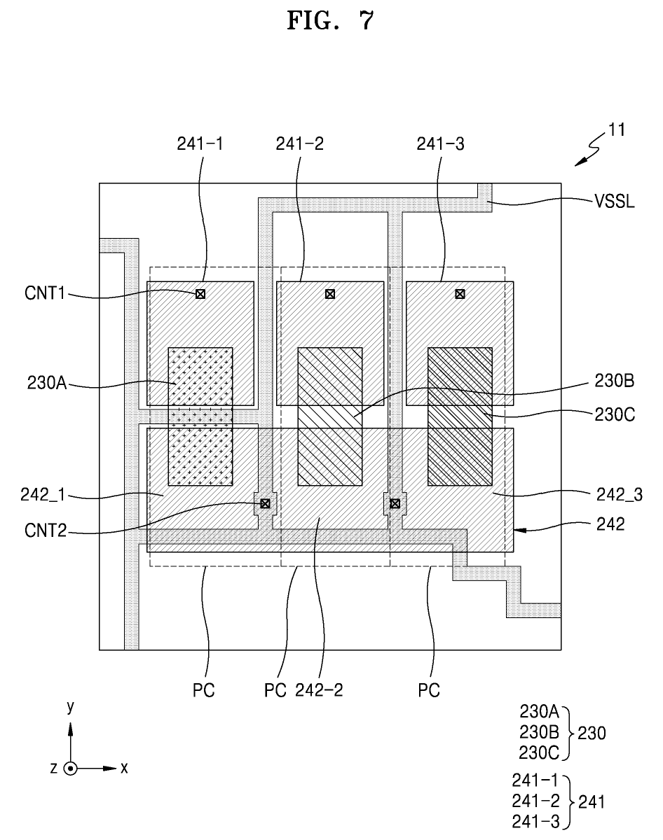

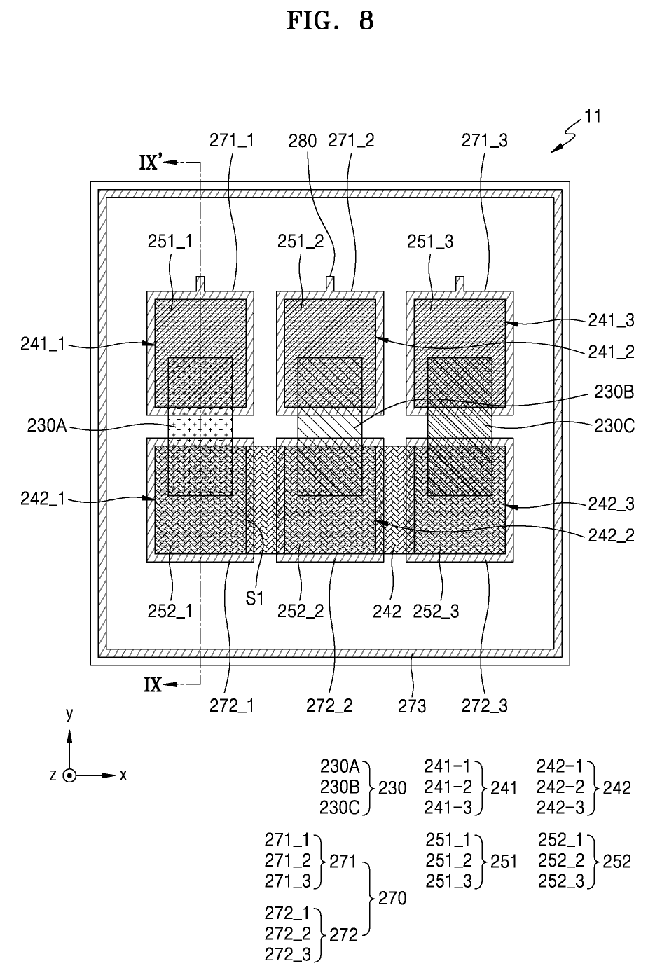

FIG. 7 is a plan view schematically showing an embodiment of the first island portion 11 of the display apparatus, according to the disclosure. For convenience of description, FIG. 7 does not illustrate dam portions and mainly shows an arrangement of electrode pads. Dam portions will be described in detail with reference to FIG. 8.

Referring to FIG. 7, light-emitting elements may be arranged in the first island portion 11. In an embodiment, FIG. 7 illustrates that the light-emitting elements arranged in the first island portion 11 include first to third light-emitting diodes 230A, 230B, and 230C emitting light of different colors. In an embodiment, one of the first to third light-emitting diodes 230A, 230B, and 230C may emit red light, another one may emit green light, and the remaining one may emit blue light, for example.

In an embodiment, FIG. 7 illustrates three light-emitting diodes 230 and three first electrode pads 241 respectively corresponding to the light-emitting diodes 230, but the disclosure is not limited thereto. In another embodiment, two or at least four light-emitting diodes 230 may be arranged in the first island portion 11, and two or at least four first electrode pads 241 may be arranged in the first island portion 11. Hereinafter, for convenience of description, it is described that three light-emitting diodes 230 and three first electrode pads 241 are arranged in the first island portion 11.

Each of the light-emitting diodes 230 may be electrically connected to the pixel driving circuit portion PC through a first electrode pad 241 (or a first electrode layer), and electrically connected to the second voltage line VSSL that is a common power line through a second electrode pad 242 (or a second electrode layer).

The first electrode pads 241 may be spaced apart from each other in one direction, e.g., the first direction (e.g., the x direction or the -x direction). In this regard, FIG. 7 illustrates the first electrode pads 241 including a first-1 electrode pad 241-1, a first-2 electrode pad 241-2, and a first-3 electrode pad 241-3. The first-1 electrode pad 241-1, the first-2 electrode pad 241-2, and the first-3 electrode pad 241-3 may be spaced apart from each other in the first direction (e.g., the x direction or the -x direction). The first-1 electrode pad 241-1 and the first-3 electrode pad 241-3 may be arranged on opposite sides with the first-2 electrode pad 241-2 therebetween. The first-1 electrode pad 241-1, the first-2 electrode pad 241-2, and the first-3 electrode pad 241-3 may be electrically connected to the corresponding pixel driving circuit portion PC, e.g., a transistor, through a first contact hole CNT1.

The second electrode pad 242 may be spaced apart from the first electrode pads 241 in a direction crossing an arrangement direction of the first electrode pads 241, e.g., the second direction (e.g., the y direction or the -y direction). The light-emitting elements may share one second electrode pad 242. In an embodiment, a first portion 242-1 of the second electrode pad 242 may be electrically connected to the first light-emitting diode 230A that is a first light-emitting element, a second portion 242-2 of the second electrode pad 242 may be electrically connected to the second light-emitting diode 230B that is a second light-emitting element, a third portion 242-3 of the second electrode pad 242 may be electrically connected to the third light-emitting diode 230C that is a third light-emitting element, and the first to third portions 242-1, 242-2, and 242-3 may be integrally connected to each other, for example. The second portion 242-2 of the second electrode pad 242 may be disposed between the first portion 242-1 and the third portion 242-3.

The first portion 242-1 of the second electrode pad 242 may be disposed next (adjacent) to one of the first electrode pads 241, e.g., the first-1 electrode pad 241-1, in the second direction (e.g., the y direction or the -y direction). The second portion 242-2 of the second electrode pad 242 may be disposed next (adjacent) to another one of the first electrode pads 241, e.g., the first-2 electrode pad 241-2, in the second direction (e.g., the y direction or the -y direction). The third portion 242-3 of the second electrode pad 242 may be disposed next (adjacent) to the remaining one of the first electrode pads 241, e.g., the first-3 electrode pad 241-3, in the second direction (e.g., the y direction or the -y direction).

The second electrode pad 242 may be electrically connected to the second voltage line VSSL passing the first island portion 11, through a second contact hole CNT2. The second voltage line VSSL may include a plurality of branches. One of the branches may pass between the first portion 242-1 and the second portion 242-2, and another one may pass between the second portion 242-2 and the third portion 242-3. FIG. 7 illustrates two second contact holes CNT2 arranged between the first portion 242-1 and the second portion 242-2 and between the second portion 242-2 and the third portion 242-3, but the disclosure is not limited thereto. In an embodiment, the second contact hole CNT2 may be disposed between the first portion 242-1 and the second portion 242-2 or between the second portion 242-2 and the third portion 242-3.

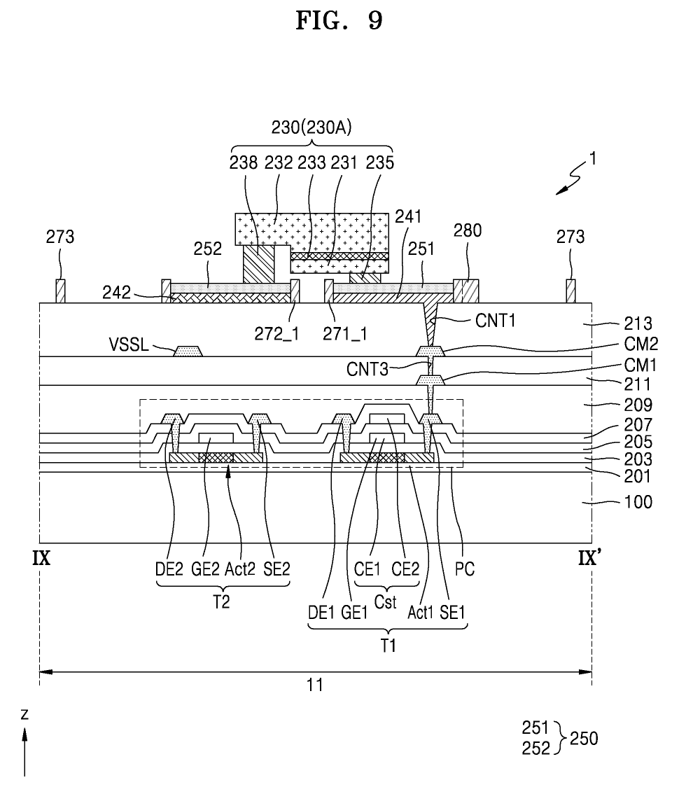

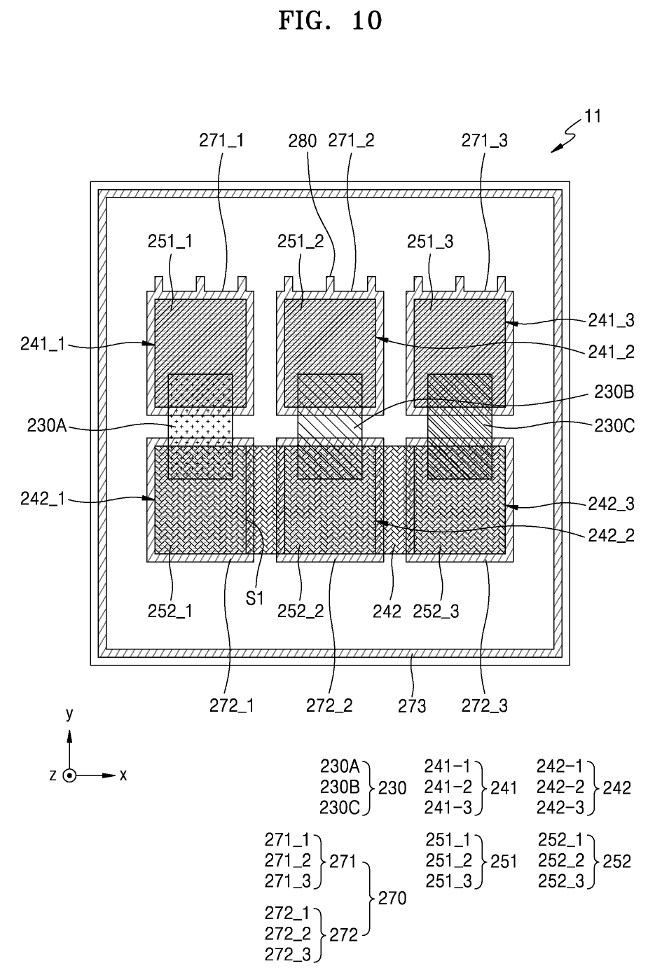

FIGS. 8 and 10 are plan views of excerpts of the first and second electrode pads 241 and 242, the light-emitting diodes 230, and dam portions 270, which are arranged in the first island portion 11 of the display apparatus 1, according to the disclosure. FIG. 9 is a cross-sectional view of the first island portion 11 of the display apparatus 1 taken along line IX-IX' of FIG. 8, according to the disclosure.

Referring to FIGS. 8 and 9, the pixel driving circuit portion PC and the light-emitting diodes 230, as the light-emitting element electrically connected to the pixel driving circuit portion PC, are arranged on the substrate 100. FIG. 8 illustrates that the light-emitting diodes 230 is the second light-emitting diode 230B in an embodiment, but the disclosure is not limited thereto. Structures of the first light-emitting diode 230A and pixel driving circuit portion PC, and structures of the third light-emitting diode 230C and pixel driving circuit portion PC are the same as structures shown in FIG. 8.

As described with reference to FIGS. 6A to 6C, the pixel driving circuit portion PC may include the transistors and the storage capacitor Cst. In this regard, FIG. 9 illustrates the first transistor T1 and the second transistor T2 among the transistors of the pixel driving circuit portion PC.

A buffer layer 201 may be disposed between the substrate 100 and the pixel driving circuit portion PC, and prevent impurities from penetrating into the transistor. The buffer layer 201 may include an inorganic insulating material, such as a silicon oxide, a silicon nitride, or a silicon oxynitride, and may include a single layer or multi-layer including the inorganic insulating material.

The first transistor T1 may include a first semiconductor layer Act1 and a first gate electrode GE1. A source region and a drain region of the first semiconductor layer Act1 may be electrically connected to a first source electrode SE1 and a first drain electrode DE1, respectively. The second transistor T2 may include a second semiconductor layer Act2 and a second gate electrode GE2. A source region and a drain region of the second semiconductor layer Act2 may be electrically connected to a second source electrode SE2 and a second drain electrode DE2, respectively.

FIG. 9 illustrates a top-gate type in which the first and second gate electrodes GE1 and GE2 are arranged on the first and second semiconductor layers Act1 and Act2 with a gate insulating layer 203 therebetween, but in another embodiment, the first and second transistors T1 and T2 may be a bottom-gate type.

In an embodiment, the first and second semiconductor layers Act1 and Act2 may include polysilicon. In an embodiment, the first and second semiconductor layers Act1 and Act2 may include amorphous silicon, an oxide semiconductor, or an organic semiconductor. The first and second gate electrodes GE1 and GE2 may include a low-resistance metal material. The first and second gate electrodes GE1 and GE2 may include a conductive material including molybdenum (Mo), aluminum (Al), copper (Cu), or titanium (Ti), and may be formed in a multi-layer or single layer including the conductive material.

The gate insulating layer 203 may include an inorganic insulating material, such as a silicon oxide, a silicon nitride, or a silicon oxynitride, and may include a single layer or multi-layer including the above-described material.

The storage capacitor Cst may include the first electrode CE1 and the second electrode CE2, which overlap each other with a first inter-insulating layer 205 therebetween. In an embodiment, the storage capacitor Cst may overlap the first transistor T1. In this regard, FIG. 9 illustrates that the first gate electrode GE1 of the first transistor T1 is the first electrode CE1 of the storage capacitor Cst. In another embodiment, the storage capacitor Cst may not overlap the first transistor T1. The storage capacitor Cst may be covered by a second inter-insulating layer 207. The second electrode CE2 of the storage capacitor Cst may include a conductive material including Mo, Al, Cu, or Ti, and may be formed in a multi-layer or single layer including the above material.

The first and second source electrodes SE1 and SE2 and the first and second drain electrodes DE1 and DE2 may be arranged in a same layer, e.g., on the second inter-insulating layer 207, and include a same material as each other. The first and second source electrodes SE1 and SE2 and the first and second drain electrodes DE1 and DE2 may include a conductive material including Mo, Al, Cu, or Ti, and may be formed in a multi-layer or single layer including the above material.

The first inter-insulating layer 205 and the second inter-insulating layer 207 may include an inorganic insulating material, such as a silicon oxide, a silicon nitride, or a silicon oxynitride, and may include a single layer or multi-layer including the above-described inorganic insulating material. The first and second transistors T1 and T2 and the storage capacitor Cst may be covered by a first organic insulating layer 209.

A second organic insulating layer 211 and a third organic insulating layer 213 may be sequentially arranged on the first organic insulating layer 209. The first organic insulating layer 209, the second organic insulating layer 211, and the third organic insulating layer 213 may include an organic insulating material. In embodiments, the organic insulating material may include a general-purpose polymer such as polymethylmethacrylate (“PMMA”) or polystyrene (“PS”), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, and any combinations thereof.

The second voltage line VSSL may be disposed on the second organic insulating layer 211. Although not illustrated, the first voltage line VDDL (FIGS. 6A to 6C) may be disposed on the first organic insulating layer 209 or disposed on the second organic insulating layer 211.

The first electrode pads 241 may be arranged on the third organic insulating layer 213. The first electrode pads 241 may be connected to a second contact metal CM2 through the first contact hole CNT1, and the second contact metal CM2 may be connected to a first contact metal CM1 through a third contact hole CNT3. FIG. 9 illustrates that the first electrode pads 241 is electrically connected to the first transistor T1 through the first and second contact metals CM1 and CM2, but the disclosure is not limited thereto. As described with reference to FIGS. 6B and 6C, the pixel driving circuit portion PC may further include the sixth transistor T6 (FIGS. 6B and 6C), and in this case, the first electrode pads 241 may be electrically connected to the sixth transistor T6 (FIGS. 6B and 6C) through the first and second contact metals CM1 and CM2. The sixth transistor T6 (FIGS. 6B and 6C) may have substantially a same structure as that of the first transistor T1.

The second electrode pad 242 may be disposed in a same layer as the first electrode pads 241, e.g., on the third organic insulating layer 213. As described above with reference to FIG. 7, the second electrode pad 242 may be electrically connected to the second voltage line VSSL through the second contact hole CNT2 (FIG. 7).

The light-emitting diode 230 may be an inorganic light-emitting diode. In an embodiment, the light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232, for example.

The first semiconductor layer 231 may include a p-type semiconductor layer, for example. The p-type semiconductor layer may include or consist of semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, and AlInN, and a p-type dopant, such as Mg, Zn, Ca, Sr, or Ba, may be doped.

The second semiconductor layer 232 may include an n-type semiconductor layer, for example. The n-type semiconductor layer may include or consist of semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, and AlInN, and an n-type dopant, such as Si, Ge, or Sn, may be doped.

The intermediate layer 233 is a region where electrons and holes recombine, and when the electrons and holes recombine, the intermediate layer 233 may transit to a relatively low energy level and generate light having a corresponding wavelength. The intermediate layer 233 may include a semiconductor material having a composition formula of InₓAl_{y}Ga_{1-x-y}N (0≤x≤1, 0≤y≤1, 0≤x+y≤1), for example, and may have a single quantum well structure or a multi quantum well (“MQW”) structure. Also, the intermediate layer 233 may have a quantum wire structure or a quantum dot structure.

In FIG. 9, the first semiconductor layer 231 includes the p-type semiconductor layer and the second semiconductor layer 232 includes the n-type semiconductor layer, but the disclosure is not limited thereto. In another embodiment, the first semiconductor layer 231 may include the n-type semiconductor layer and the second semiconductor layer 232 may include the p-type semiconductor layer.

The first electrode 235 and the second electrode 238 of the light-emitting diode 230 may be electrically connected to the first electrode pad 241 and the second electrode pad 242, respectively, through a bump metal 250.

The light-emitting diode 230 may be electrically connected to the first electrode pad 241 and the second electrode pad 242 by arranging the bump metal 250 on each of the first electrode pad 241 and the second electrode pad 242, applying predetermined heat, and then arranging the light-emitting diode 230 through predetermined pressure. In an embodiment, the light-emitting diode 230 may be electrically connected to the first electrode pad 241 through a first bump metal 251 between the light-emitting diode 230 and the first electrode pad 241, for example. The light-emitting diode 230 may be electrically connected to the second electrode pad 242 through a second bump metal 252 between the light-emitting diode 230 and the second electrode pad 242.

Referring to FIGS. 7 to 9, the bump metal 250 may be disposed on each corresponding electrode pad. The first bump metal 251 may be disposed on each of the first-1 electrode pad 241-1, the first-2 electrode pad 241-2, and the first-3 electrode pad 241-3. In an embodiment, a first-1 bump metal 251-1 may be disposed on the first-1 electrode pad 241-1, a first-2 bump metal 251-2 may be disposed on the first-2 electrode pad 241-2, and a first-3 bump metal 251-3 may be disposed on the first-3 electrode pad 241-3, for example. In this case, the first bump metal 251 may have a same size as the first electrode pad 241 and overlap the same in a plan view. In an embodiment, the first-1 bump metal 251-1 may overlap the first-1 electrode pad 241-1, the first-2 bump metal 251-2 may overlap the first-2 electrode pad 241-2, and the first-3 bump metal 251-3 may overlap the first-3 electrode pad 241-3, for example.

The second bump metal 252 may be disposed on the second electrode pad 242, e.g., in the first to third portions 242-1, 242-2, and 242-3. In an embodiment, a second-1 bump metal 252-1 may be disposed in the first portion 242-1, a second-2 bump metal 252-2 may be disposed in the second portion 242-2, and a second-3 bump metal 252-3 may be disposed in the third portion 242-3, for example. In this case, the second bump metal 252 may overlap the second electrode pad 242 in a plan view. In an embodiment, the second-1 bump metal 252-1 may overlap the first portion 242-1, the second-2 bump metal 252-2 may overlap the second portion 242-2, and the second-3 bump metal 252-3 may overlap the third portion 242-3, for example.

In an embodiment, the bump metal 250 may include a metal such as gold (Au), nickel (Ni), and indium (In).

The dam portions 270 may be arranged on the third organic insulating layer 213. In an embodiment, the dam portions 270 may include a first dam portion 271, a second dam portion 272, and a third dam portion 273. In an embodiment, the dam portions 270 may include an organic material.

In an embodiment, the first dam portion 271 may surround the first electrode pad 241, on the third organic insulating layer 213. Also, the first dam portion 271 may surround the first bump metal 251 electrically connected to the first electrode pad 241. In an embodiment, a first-1 dam portion 271-1 may surround the first-1 electrode pad 241-1 and the first-1 bump metal 251-1, a first-2 dam portion 271-2 may surround the first-2 electrode pad 241-2 and the first-2 bump metal 251-2, and a first-3 dam portion 271-3 may surround the first-3 electrode pad 241-3 and the first-3 bump metal 251-3, for example. In this case, in an embodiment, each first dam portion 271 may be formed in a closed loop.

The first dam portions 271, e.g., the first-1 dam portion 271-1, the first-2 dam portion 271-2, and the first-3 dam portion 271-3, may be spaced apart from each other in one direction, e.g., the first direction (e.g., the x direction or the -x direction). The first-1 dam portion 271-1 and the first-3 dam portion 271-3 may be arranged on opposite sides with the first-2 dam portion 271-2 therebetween.

In an embodiment, the first dam portion 271 may include a shape corresponding to a shape of the first bump metal 251. In an embodiment, when the first bump metal 251 is provided as a quadrangle in a plan view, the first dam portion 271 may be provided in the shape of a quadrangular frame to surround the first bump metal 251, for example. However, the disclosure is not limited thereto, and it may be understood that the first dam portion 271 may be provided in any shape corresponding to a shape of the first bump metal 251 to surround the first bump metal 251.

An inner surface of the first dam portion 271 may contact the first bump metal 251. In other words, the first dam portion 271 may prevent the first bump metal 251 from deviating outside the first dam portion 271. Also, a height of the first dam portion 271 may be greater than a height of each of the first electrode pad 241 and the first bump metal 251, and greater than the sum of the heights of the first electrode pad 241 and the first bump metal 251.

The second dam portion 272 may surround a portion of the second electrode pad 242, on the third organic insulating layer 213. Also, the second dam portion 272 may surround the second bump metal 252 electrically connected to the second electrode pad 242. In an embodiment, a second-1 dam portion 272-1 may surround the first portion 242-1 and the second-1 bump metal 252-1, a second-2 dam portion 272-2 may surround the second portion 242-2 and the second-2 bump metal 252-2, and a second-3 dam portion 272-3 may surround the third portion 242-3 and the second-3 bump metal 252-3. In this case, in an embodiment, each second dam portion 272 may be formed in a closed loop, for example.

The second dam portions 272, e.g., the second-1 dam portion 272-1, the second-2 dam portion 272-2, and the second-3 dam portion 272-3, may be spaced apart from each other in one direction, e.g., the first direction (e.g., the x direction or the -x direction). The second-1 dam portion 272-1 and the second-3 dam portion 272-3 may be arranged on opposite sides with the second-2 dam portion 272-2 therebetween.

In an embodiment, the second dam portion 272 may include a shape corresponding to a shape of the second bump metal 252. In an embodiment, when the second bump metal 252 is provided as a quadrangle in a plan view, the second dam portion 272 may be provided in the shape of a quadrangular frame to surround the second bump metal 252, for example. However, the disclosure is not limited thereto, and it may be understood that the second dam portion 272 may be provided in any shape corresponding to a shape of the second bump metal 252 to surround the second bump metal 252.

An inner surface of the second dam portion 272 may contact the second bump metal 252. In other words, the second dam portion 272 may prevent the second bump metal 252 from deviating outside the second dam portion 272. Also, a height of the second dam portion 272 may be greater than a height of each of the second electrode pad 242 and the second bump metal 252, and greater than the sum of the heights of the second electrode pad 242 and the second bump metal 252.

As described above, the second electrode pad 242 may be integrally provided to be connected to three light-emitting elements, for example. Accordingly, a portion of the second dam portion 272 may be disposed on the second electrode pad 242. In an embodiment, the portion of the second dam portion 272 facing another second dam portion 272 may be disposed on the second electrode pad 242, and the remaining portion thereof may be disposed on the third organic insulating layer 213, for example. In other words, the portion of the second dam portion 272 facing a remaining (the other) second dam portion 272 may overlap the second electrode pad 242 in a plan view, and the remaining portion thereof may not overlap the second electrode pad 242 and may surround the second electrode pad 242.

In detail, based on the second-1 dam portion 272-1, a side S1 of the second-1 dam portion 272-1 facing the second-2 dam portion 272-2 may be disposed on the second electrode pad 242 and overlap the second electrode pad 242 in a plan view. Other sides of the second-1 dam portion 272-1 excluding the side S1 may surround the second electrode pad 242 in a plan view.

The third dam portion 273 may be disposed on the third organic insulating layer 213 along a perimeter of the first island portion 11. In other words, the third dam portion 273 may be disposed along the perimeter of the first island portion 11 in a plan view and in an embodiment, may be formed in a closed loop. Here, the first dam portions 271 and the second dam portions 272 may be disposed in the perimeter of the third dam portion 273.

In an embodiment, the third dam portion 273 may include a shape corresponding to a shape of the first island portion 11. In an embodiment, when the first island portion 11 is provided as a quadrangle in a plan view, the third dam portion 273 may be provided in the shape of a quadrangular frame along the perimeter of the first island portion 11, for example. However, the disclosure is not limited thereto, and it may be understood that the third dam portion 273 may be provided in any shape corresponding to a shape of the first island portion 11 to be disposed along the perimeter of the first island portion 11.

The third dam portion 273 may function as a dam in the perimeter of the first island portion 11 to prevent the first bump metal 251 and/or the second bump metal 252 from deviating outside the third dam portion 273. In an embodiment, a height of the third dam portion 273 may be substantially the same as a height of the first dam portion 271 and/or the second dam portion 272.

In an embodiment, the first dam portion 271, the second dam portion 272, and the third dam portion 273 may include a same material and may be arranged in a same layer. Also, the first dam portion 271, the second dam portion 272, and the third dam portion 273 may be formed through a same process.

According to a comparative embodiment of the disclosure, when the first dam portion 271, the second dam portion 272, and the third dam portion 273 are not arranged, the bump metals 250 may be pushed during a process of electrically connecting the light-emitting element to the first electrode pad 241 and the second electrode pad 242 by the bump metals 250. In an embodiment, during processes of arranging the bump metals 250 on the first electrode pad 241 and the second electrode pad 242 and then applying heat and pressure thereto to arrange the light-emitting diode 230, the bump metals 250 on the first electrode pad 241 and the second electrode pad 242 may deviate from boundaries of the first and second electrode pads 241 and 242 to surroundings of the first and second electrode pads 241 and 242 and/or uniformity of thicknesses of the bump metals 250 may be decreased, for example.

However, in embodiments of the disclosure, the dam portions 270 may be arranged and accordingly, a phenomenon of the bump metal 250 being pushed may be prevented.

In an embodiment, an align tip portion 280 may be disposed on the third organic insulating layer 213. The align tip portion 280 may be connected to at least one of the dam portions 270 to visually identify alignment after the light-emitting diode 230 is disposed. Also, an alignment degree of the light-emitting diode 230 may be quantified by measuring a misalignment degree, e.g., an angle of misalignment, of the align tip portions 280.

In an embodiment, the align tip portion 280 may protrude from one side of the first dam portion 271. In an embodiment, the align tip portion 280 may protrude from one side of the first dam portion 271, e.g., from a side opposite to a side facing the second dam portion 272, for example. The align tip portion 280 may protrude outward from the one side of the first dam portion 271 in the second direction (e.g., the y direction). In FIG. 8, one align tip portion 280 is disposed for each first dam portion 271, but the disclosure is not limited thereto. In another embodiment, as shown in FIG. 10, the plurality of align tip portions 280 may be arranged in parallel on one side of the first dam portion 271 in the first direction.

Also, in the drawings, the align tip portion 280 is provided in the shape of a line in a plan view, but the align tip portion 280 may be provided in the shape of a letter "H" or a letter "T", for example. Accordingly, alignment may be further accurately identified visually.

In an embodiment, the align tip portion 280 and the dam portions 270 may include a same material and arranged in a same layer. Also, the align tip portion 280 and the dam portions 270 may be formed through a same process. Also, a height of the align tip portion 280 may be substantially the same as a height of the dam portions 270.

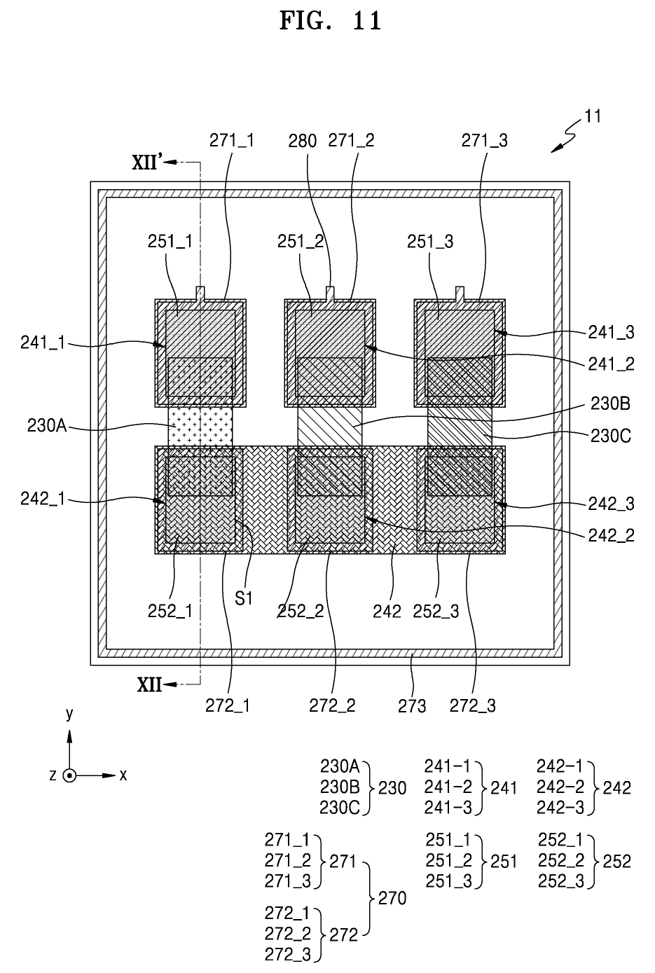

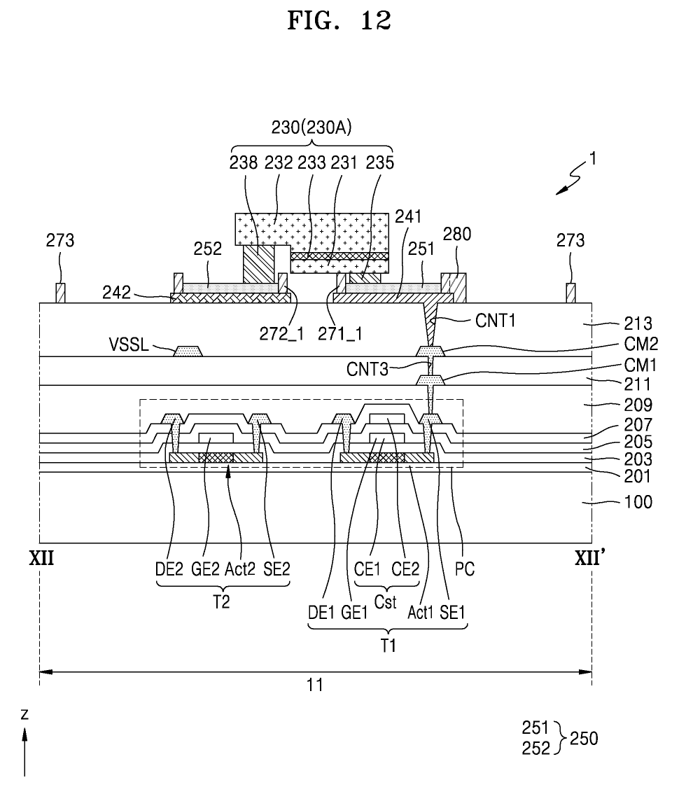

FIG. 11 is a plan view of excerpts of the first and second electrode pads 241 and 242, the light-emitting diodes 230, and dam portions 270, which are arranged in the first island portion 11 of the display apparatus 1, according to the disclosure. FIG. 12 is a cross-sectional view of the first island portion 11 of the display apparatus 1 taken along line XII-XII' of FIG. 11, according to the disclosure.

The display apparatus 1 in the illustrated embodiment is similar to that described above, and only differences will be mainly described below.

Referring to FIGS. 11 and 12, the first bump metal 251 may be disposed on the first electrode pad 241. Here, in an embodiment, the first bump metal 251 may have a smaller size than the first electrode pad 241. The first bump metal 251 may be disposed within the perimeter of the first electrode pad 241 in a plan view. In an embodiment, the first-1 bump metal 251-1 may be formed smaller than the first-1 electrode pad 241-1 to be disposed within the perimeter of the first-1 electrode pad 241-1, the first-2 bump metal 251-2 may be formed smaller than the first-2 electrode pad 241-2 to be disposed within the perimeter of the first-2 electrode pad 241-2, and the first-3 bump metal 251-3 may be formed smaller than the first-3 electrode pad 241-3 to be disposed within the perimeter of the first-3 electrode pad 241-3, for example.

Also, the second bump metal 252 may be disposed on the second electrode pad 242. Here, in an embodiment, the second bump metal 252 may be disposed within the perimeter of the second electrode pad 242. In an embodiment, the second-1 bump metal 252-1 may be disposed within the perimeter of the first portion 242-1, the second-2 bump metal 252-2 may be disposed within the perimeter of the second portion 242-2, and the second-3 bump metal 252-3 may be disposed within the perimeter of the third portion 242-3, for example.

In an embodiment, the first dam portion 271 may be disposed on the first electrode pad 241. The first dam portion 271 may be disposed in a same layer as the first bump metal 251, e.g., on the first electrode pad 241, and may surround the first bump metal 251. Accordingly, the first dam portion 271 may be disposed along the perimeter of the first electrode pad 241, within the perimeter of the first electrode pad 241.

Here, because the align tip portion 280 is connected to one side of the first dam portion 271, a portion of the align tip portion 280 may be disposed on the first electrode pad 241 and another portion of the align tip portion 280 may be disposed on the third organic insulating layer 213 outside the first electrode pad 241.

In an embodiment, the second dam portion 272 may be disposed on the second electrode pad 242. The second dam portion 272 may be disposed in a same layer as the second bump metal 252, e.g., on the second electrode pad 242, and may surround the second bump metal 252. Accordingly, the second dam portion 272 may be disposed within the perimeter of the second electrode pad 242 and along the perimeters of the first portion 242-1, the second portion 242-2, and the third portion 242-3.

In such an embodiment as well, the first dam portion 271 and the second dam portion 272 respectively completely surround the first bump metal 251 and the second bump metal 252, and thus, the first bump metal 251 and the second bump metal 252 may be prevented from being deviated outside the first dam portion 271 and the second dam portion 272.

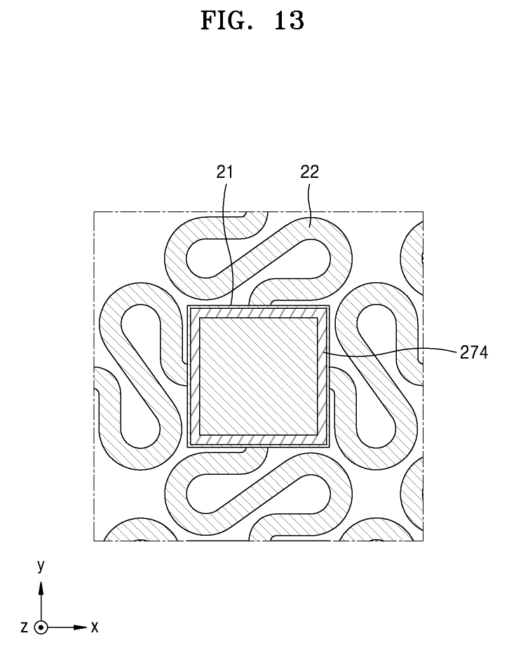

FIG. 13 is a plan view schematically showing the second island portion 21 of the display apparatus 1, according to the disclosure. FIG. 13 is an enlarged view of one of the second island portions 21 arranged in the first non-display area NDA1 described above with reference to FIGS. 4A to 4C. Hereinafter, for convenience of description, the second island portion 21 shown in FIG. 4C will be mainly described.

Referring to FIG. 4C and 13, the second island portions 21 may be spaced apart from each other in the first direction (e.g., the x direction or the -x direction) and the second direction (e.g., the y direction or the -y direction). The second island portions 21 that are spaced apart from each other may be connected to each other by the second bridge portion 22. The second island portion 21 in an embodiment may include circuits such as a driver of the gate driving circuit GDC (refer to FIG. 2). In an alternative embodiment, the second island portion 21 may include wires for connecting the display area DA to the circuits.

A fourth dam portion 274 may be disposed in the second island portion 21. In an embodiment, the fourth dam portion 274 may be disposed on the third organic insulating layer 213 of the second island portion 21 along the perimeter of the second island portion 21. In other words, the fourth dam portion 274 may be disposed along the perimeter of the second island portion 21 in a plan view and in an embodiment, may be formed in a closed loop.

In an embodiment, the fourth dam portion 274 may include a shape corresponding to a shape of the second island portion 21. In an embodiment, when the second island portion 21 is provided as a quadrangle in a plan view, the fourth dam portion 274 may be provided in the shape of a quadrangular frame along the perimeter of the second island portion 21, for example. However, the disclosure is not limited thereto, and it may be understood that the fourth dam portion 274 may be provided in any shape corresponding to a shape of the second island portion 21 to be disposed along the perimeter of the second island portion 21.

In an embodiment, the fourth dam portion 274 may include a same material and may be disposed in a same layer as at least one of the first dam portion 271, the second dam portion 272, and the third dam portion 273. Also, the fourth dam portion 274 may be formed through a same process as at least one of the first dam portion 271, the second dam portion 272, and the third dam portion 273.

The fourth dam portion 274 may supplement strength of the second island portion 21. The display apparatus 1 may be stretched in a plurality of directions by an external force as described above. When the display apparatus 1 is stretched, a predetermined portion of an island portion, e.g., the second island portion 21, may be stretched more than other portions and become thinner due to a step on a surface. This may cause structural weakness of the island portion.

In the illustrated embodiment, the fourth dam portion 274 may be disposed along the perimeter of the second island portion 21 to which an external force is mostly applied, thereby distributing the external force applied to the perimeter of the second island portion 21. Accordingly, the strength of the second island portion 21 may be supplemented, and the second island portion 21, and wires and a circuit, such as a driver, which are arranged in the second island portion 21, may be protected.

In FIG. 13, one fourth dam portion 274 is disposed in the second island portion 21, but the disclosure is not limited thereto. In an embodiment, a plurality of the fourth dam portions 274, e.g., two fourth dam portions 274, may be arranged in the second island portion 21.

In this case, a fourth-1 dam portion may be disposed along the perimeter of the second island portion 21 in a plan view. A fourth-2 dam portion may be disposed on an inner side of a perimeter of the fourth-1 dam portion and disposed along the perimeter of the second island portion 21. As such, when the plurality of fourth dam portions 274 are arranged in the second island portion 21, an external force may be further effectively distributed, and the second island portion 21, and the wires and the circuit, such as the driver, which are arranged in the second island portion 21, may be protected.

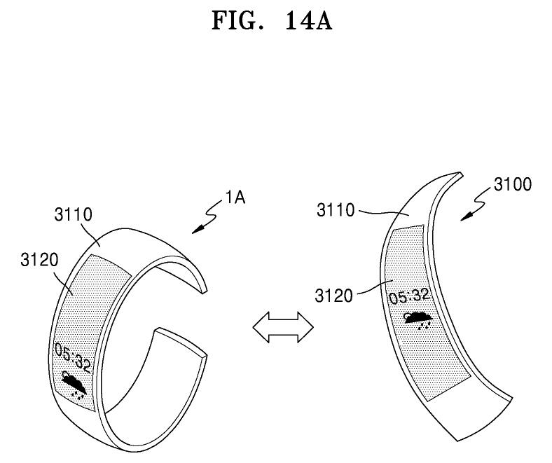

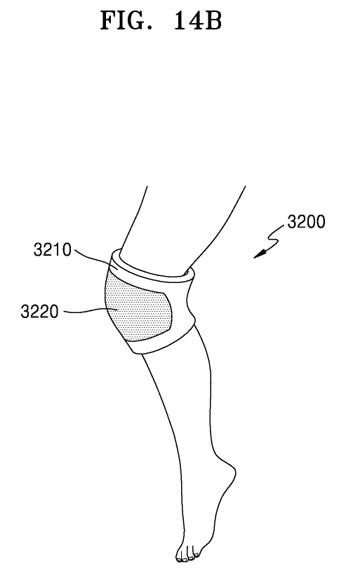

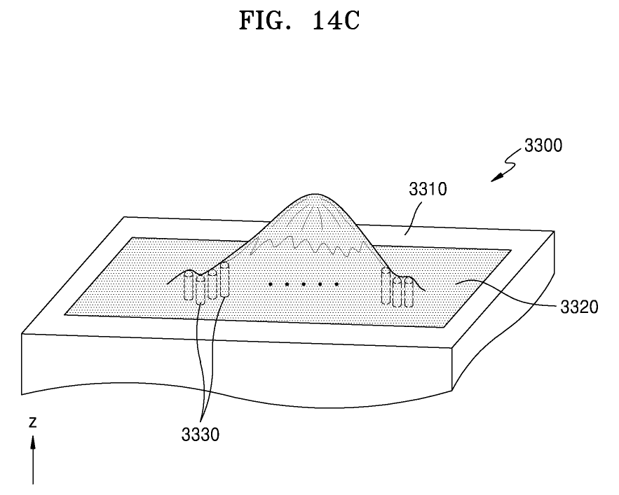

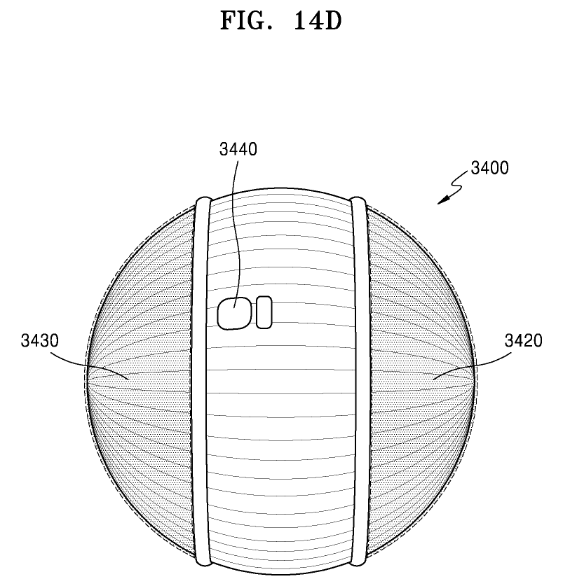

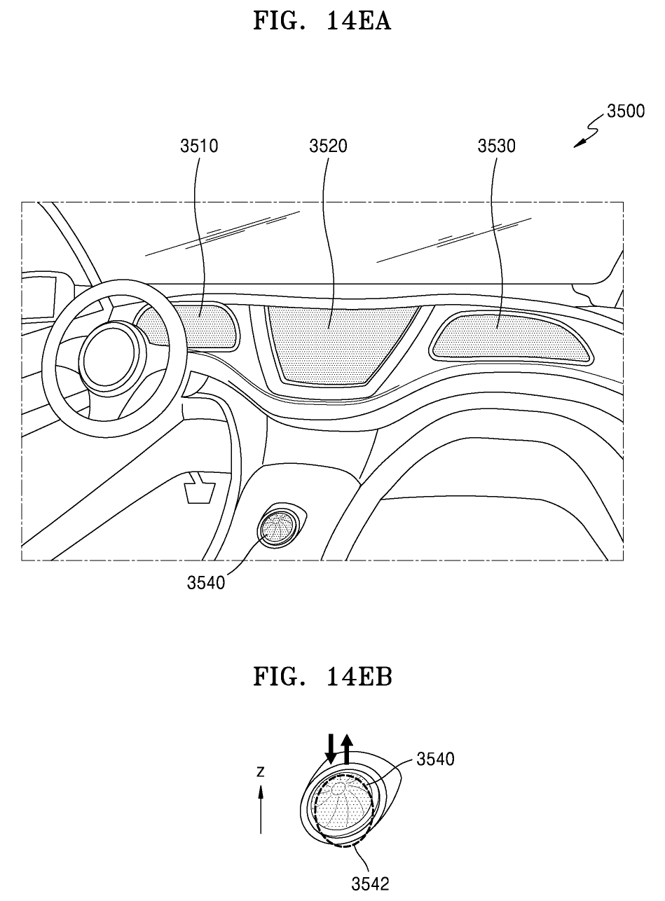

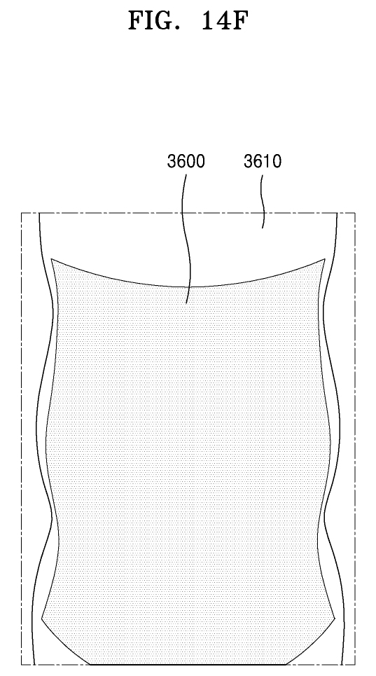

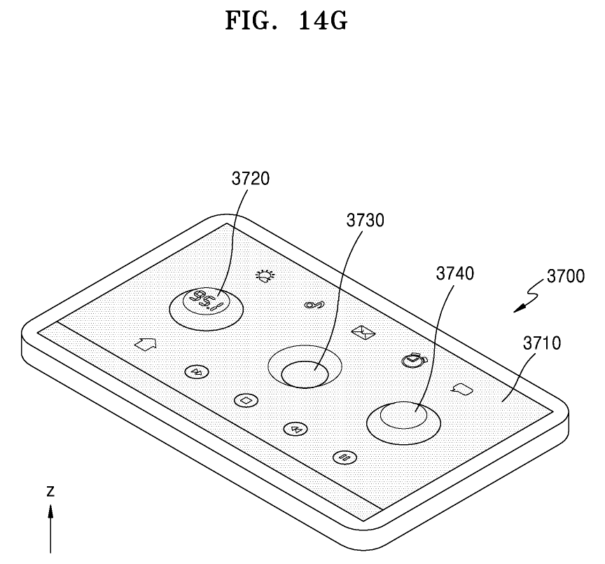

FIGS. 14A to 14G are each a perspective view of an embodiment of an electronic device including a display apparatus, according to the disclosure.

Referring to FIG. 14A, a display apparatus in an embodiment of the disclosure may be used for a wearable electronic device 3100 that may be worn on a part of the body of a user. The wearable electronic device 3100 may include a body portion 3110 and a display portion 3120 provided in the body portion 3110. The display apparatus in embodiments of the disclosure may be used as the display portion 3120 of the wearable electronic device 3100. The wearable electronic device 3100 of FIG. 14A may be transformed. In an embodiment, the wearable electronic device 3100 may be used as a smart watch or a smart phone according to the user's choice.

FIG. 14B illustrates a medical electronic device 3200. In an embodiment, the medical electronic device 3200 may include a body portion 3210 and a light-emitting portion 3220. The display apparatus in embodiments of the disclosure may be used as the light-emitting portion 3220 of the medical electronic device 3200. The light-emitting portion 3220 may emit, to the body of a patient, light of a uniform wavelength band (e.g., infrared light, visible light, or the like). In an embodiment, the body portion 3210 may include an elastic fiber material and have a structure capable of being worn on the body of a user.

FIG. 14C illustrates an educational electronic device 3300. In an embodiment, the educational electronic device 3300 may include a display portion 3320 provided in a frame 3310. The display portion 3320 may use a display apparatus according to the disclosure. An image of the sea with waves, a mountain covered with snow, or a volcano with lava may be provided through the display portion 3320, and at this time, the display portion 3320 may be stretched in a height direction (e.g., the z direction) by reflecting the height of waves, mountain, or volcano. In some embodiments, a portion of the display portion 3320 may 3-dimensionally display movement of the lava as a height thereof sequentially changes in a direction the lava flows. The educational electronic device 3300 may include a plurality of strokes 3330 arranged below the display portion 3320, e.g., below a rear surface of the display portion 3320, such that the display portion 3320 is stretched in the height direction. An image displayed on the display portion 3320 may be 3-dimensionally realized to have heights as the strokes 3330 move in the third direction (e.g., the z direction or the -z direction). In an embodiment, haptic information may be provided through the strokes 3330. FIG. 14C shows the educational electronic device 3300, but the purpose thereof is not limited as long as information about a predetermined image is provided.

Electronic devices shown in FIGS. 14A to 14C have variable shapes, but the disclosure is not limited thereto. As will be described in following embodiments, a display apparatus in embodiments of the disclosure may be used for an electronic device in which a portion representing an image (e.g., a screen) is fixed.

FIG. 14D illustrates a robot 3400 as an electronic device according to the disclosure. The robot 3400 may recognize movement or an object by a camera portion 3440 and display a predetermined image to a user through display portions 3420 and 3430. In some embodiments, display apparatuses in an embodiment of the disclosure may be stretched in various directions as described above, and thus may be assembled to a body frame having a hemispherical shape, and accordingly, the robot 3400 may include hemispherical display portions 3420 and 3430.

FIG. 14EA illustrates a vehicle display apparatus 3500 as an electronic device according to the disclosure, and FIG. 14EB is an enlarged view of a portion of FIG. 14EA. The vehicle display apparatus 3500 may include a cluster 3510, a center information display (“CID”) 3520, and/or a passenger display 3530. A display apparatus in an embodiment of the disclosure may be stretched in various directions, and thus may be used for the cluster 3510, the CID 3520, and/or the passenger display 3530 without being restricted by a shape of an internal frame of a vehicle.

FIG. 14EA illustrates that the cluster 3510, the CID 3520, and/or the passenger display 3530 are separated from each other, but the disclosure is not limited thereto. In another embodiment, two or more of the cluster 3510, the CID 3520, and the passenger display 3530 may be integrated with each other.

In some embodiments, the vehicle display apparatus 3500 may include a button 3540 for representing a predetermined image. Referring to an enlarged view of FIG. 14EB, the hemispherical button 3540 may include an object 3542 providing a feeling of using a button while moving in the z direction or the -z direction, and a display apparatus disposed on the object 3542. In some embodiments, when the object 3542 has a 3-dimensionally rounded surface, the display apparatus may also have the 3-dimensionally rounded surface.

FIG. 14F illustrates an electronic device in an embodiment of the disclosure used as an advertising or exhibitory electronic device 3600. In some embodiments, the advertising or exhibitory electronic device 3600 may be installed at a fixed structure 3610, such as a wall or a pillar. When the structure 3610 includes an uneven surface as shown in FIG. 14F, the advertising or exhibitory electronic device 3600 may also be disposed along the uneven surface of the structure 3610. In some embodiments, the advertising or exhibitory electronic device 3600 may be installed at the structure 3610 by a thermal contraction film or the like.

FIG. 14G illustrates a controller 3700 as an electronic device according to the disclosure. The controller 3700 may include an image type button. In an embodiment, the controller 3700 may include first to third button areas 3720 to 3740 provided as a partial area of a display portion 3710 protrudes in a z direction or protrudes in a -z direction (or be sunken in the z direction), for example. In some embodiments, the first and third button areas 3720 and 3740 may protrude in the z direction, and the second button 3730 may protrude in the -z direction (or be sunken in the z direction).

The disclosure has been described with reference to embodiments shown in the drawings, but the embodiments are merely illustrative embodiments. One of ordinary skill in the art may fully understand that other various modifications and equivalent embodiments are possible from the embodiments. Accordingly, the true technical protection scope of the disclosure will be defined based on the appended claims.

What is claimed is:

1. A display apparatus comprising:
a substrate;
a transistor disposed on the substrate;
a first-1 electrode pad electrically connected to the transistor;
a first-1 bump metal connected to the first-1 electrode pad;
a first light-emitting element electrically connected to the first-1 electrode pad through the first-1 bump metal; and
a first-1 dam portion surrounding the first-1 bump metal.

2. The display apparatus of claim 1, wherein an inner side of the first-1 dam portion contacts the first-1 bump metal.

3. The display apparatus of claim 1, wherein, in a plan view, the first-1 dam portion is disposed outside the first-1 electrode pad to surround the first-1 electrode pad.

4. The display apparatus of claim 1, wherein, in a plan view, the first-1 dam portion is disposed on the first-1 electrode pad along a perimeter of the first-1 electrode pad.

5. The display apparatus of claim 1, further comprising at least one align tip portion protruding from one side of the first-1 dam portion.

6. The display apparatus of claim 5, wherein the at least one align tip portion comprises a same material as a material of the first-1 dam portion.

7. The display apparatus of claim 1, further comprising:
a second electrode pad disposed next to the first-1 electrode pad;
a second-1 bump metal connected to the second electrode pad to electrically connect the second electrode pad and the first light-emitting element to each other; and
a second-1 dam portion surrounding the second-1 bump metal.

8. The display apparatus of claim 7, wherein the second electrode pad is electrically connected to a common power line.

9. The display apparatus of claim 7, further comprising:
a first-2 electrode pad spaced apart from the first-1 electrode pad in a first direction;
a first-2 bump metal connected to the first-2 electrode pad and electrically connecting the first-2 electrode pad to a second light-emitting element; and
a first-2 dam portion surrounding the first-2 bump metal.

10. The display apparatus of claim 9, wherein the second electrode pad is spaced apart from the first-1 electrode pad and the first-2 electrode pad in a second direction crossing the first direction.

11. The display apparatus of claim 7, further comprising:
a second-2 bump metal connected to the second electrode pad to electrically connect the second electrode pad and a second light-emitting element to each other; and
a second-2 dam portion surrounding the second-2 bump metal,
wherein, in a plan view, the second electrode pad overlaps the second-1 bump metal and the second-2 bump metal.

12. The display apparatus of claim 11, wherein the second-1 dam portion and the second-2 dam portion are spaced apart from each other in a first direction.

13. The display apparatus of claim 11, wherein a portion of the second-1 dam portion facing the second-2 dam portion is disposed on the second electrode pad, and a remaining portion of the second-1 dam portion is disposed outside the second electrode pad.

14. The display apparatus of claim 7, wherein the first-1 dam portion comprises a same material as a material of the second-1 dam portion, and
the first-1 dam portion and the second-1 dam portion are arranged in a same layer.

15. A display apparatus comprising a display area and a non-display area outside the display area, the display apparatus further comprising:
a plurality of first island portions arranged in the display area, each of the plurality of first island portions comprising:
a substrate;
a transistor disposed on the substrate;
a first electrode pad electrically connected to the transistor;
a first bump metal connected to the first electrode pad;
a first light-emitting element electrically connected to the first electrode pad through the first bump metal; and
a first dam portion surrounding the first bump metal; and
a first bridge portion connecting two first island portions next to each other from among the plurality of first island portions.

16. The display apparatus of claim 15, wherein each of the plurality of first island portions further comprises a third dam portion disposed along a perimeter of each of the plurality of first island portions.

17. The display apparatus of claim 16, wherein the third dam portion comprises a same material as a material of the first dam portion and is disposed in a same layer as the first dam portion.

18. The display apparatus of claim 16, further comprising:
a plurality of second island portions arranged in the non-display area; and
a second bridge portion connecting two second island portions next to each other from among the plurality of second island portions,
each of the plurality of second island portions comprises a fourth dam portion disposed along a perimeter of each of the plurality of second island portions.

19. The display apparatus of claim 18, wherein the fourth dam portion comprises a same material as a material of the third dam portion and is disposed in a same layer as the third dam portion.

20. An electronic device comprising:
a display apparatus comprising:
a substrate;
a transistor disposed on the substrate;
a first electrode pad electrically connected to the transistor;
a first bump metal connected to the first electrode pad;
a first light-emitting element electrically connected to the first electrode pad through the first bump metal; and
a first dam portion surrounding the first bump metal;
a frame accommodating the display apparatus.
